(19) United States
(12) Patent Application Publication
(10) Pub. No.: US 2024/0244918 A1
(43) Pub. Date: Jul. 18, 2024

(54) DISPLAY DEVICE AND MANUFACTURING METHOD OF THE SAME

(71) Applicant: Samsung Display Co., Ltd., Yongin-si (KR)

(72) Inventors: SOODONG KIM, Yongin-si (KR); SUNYOUNG KWON, Yongin-si (KR); JINWON KIM, Yongin-si (KR); HYE-JIN PAEK, Yongin-si (KR); TAEYOUNG SONG, Yongin-si (KR)

(73) Assignee: Samsung Display Co., Ltd., Yongin-si (KR)

(21) Appl. No.: 18/490,874

(22) Filed: Oct. 20, 2023

(30) Foreign Application Priority Data
Jan. 16, 2023 (KR) 10-2023-0005989

(51) Int. Cl. H10K 59/38; H10K 59/12; H10K 59/80

(52) U.S. Cl. CPC H10K 59/38; H10K 59/1201; H10K 59/8792

(57) ABSTRACT

A display device includes a display panel that provides source light and a light control member disposed on the display panel and including light control parts and a division pattern layer that divides the light control parts, wherein the division pattern layer includes first barrier rib portions extending in a first direction and spaced apart from each other by a first distance in a second direction perpendicular to the first direction, wherein the light control parts are disposed between the first barrier rib portions, second barrier rib portions extending in the second direction and spaced apart from each other in the first direction, wherein the light control part are disposed between the second barrier rib portions, and dam portions spaced apart from each other in the second direction by a second distance greater than the first distance.

### CROSS-REFERENCE TO RELATED APPLICATION(S)

This application claims priority to and benefits of Korean Patent Application No. 10-2023-0005989 under 35 U.S.C. § 119, filed on Jan. 16, 2023, the entire contents of which are incorporated herein by reference.

### BACKGROUND

### 1. Technical Field

Embodiments relate to a display device including a light control part manufactured by an inkjet printing method and a method of manufacturing the display device.

### 2. Description of the Related Art

Display devices include a transmissive display device that selectively transmits source light generated from a light source and a light-emitting display device that generates source light in the display device. The display devices may include different types of light control parts according to pixels in order to generate an image. A light control part may transmit source light of some wavelength ranges or change the color of the source light.

The light control part may be formed by an inkjet printing method, and in order to implement a high-resolution display device, it is necessary to maintain the uniform print quality of each light control part without color mixing between neighboring light control parts.

### SUMMARY

Embodiments provide a display device including a light control part having excellent appearance quality.

Embodiments also provide a method of manufacturing a display device, which forms a light control part to have excellent print quality.

However, embodiments of the disclosure are not limited to those set forth herein. The above and other embodiments will become more apparent to one of ordinary skill in the art to which the disclosure pertains by referencing the detailed description of the disclosure given below.

In an embodiment, a display device may include: a display panel that provides source light; and a light control member disposed on the display panel and including a plurality of light control parts and a division pattern layer that divides the plurality of light control parts, wherein the division pattern layer may include: a plurality of first barrier rib portions extending in a first direction and spaced apart from each other by a first distance in a second direction perpendicular to the first direction, wherein the plurality of light control parts may be disposed between the plurality of first barrier rib portions; a plurality of second barrier rib portions extending in the second direction and spaced apart from each other in the first direction, wherein the plurality of light control parts may be disposed between the plurality of second barrier rib portions; and a plurality of dam portions spaced apart from each other in the second direction by a second distance greater than the first distance.

In an embodiment, the plurality of light control parts may include: a plurality of first light control parts that emit light of a first wavelength range and arranged in the first direction; and a plurality of second light control parts that emit light of a second wavelength range, respectively spaced apart from the plurality of first light control parts in the second direction, and arranged in the first direction.

In an embodiment, each of the plurality of dam portions may be disposed at an upper end portion or a lower end portion of each of the plurality of light control parts spaced apart from each other in the first direction, or disposed at a central portion of a length of each of the plurality of light control parts in the first direction.

In an embodiment, the division pattern layer may include: a lower pattern layer including the plurality of first barrier rib portions and the plurality of second barrier rib portions; and an upper pattern layer disposed on the lower pattern layer and including the plurality of dam portions.

In an embodiment, the plurality of dam portions may have liquid repellency.

In an embodiment, a plurality of openings may be defined by the plurality of first barrier rib portions and the plurality of second barrier rib portions, and a dam opening may be defined between neighboring dam portions in the second direction.

In an embodiment, the dam opening may be defined on the plurality of second barrier rib portions.

In an embodiment, each of the plurality of light control parts may be disposed in each of the openings, and a remaining light control part, which is formed of a same material as that of the light control part adjacent to the remaining light control part in the first direction may be disposed in the dam opening.

In an embodiment, the shape of the dam opening in a plan view defined by the plurality of dam portions spaced apart from each other in the second direction and the edge portions of the plurality of light control parts neighboring each other in the first direction may be a polygon including a portion in which a distance between the neighboring dam portions is maximized in the second direction.

In an embodiment, the upper pattern layer may be disposed on the lower pattern layer and further include connection dam portions extending from the plurality of dam portions in the second direction.

In an embodiment, the plurality of light control parts may include: n first light control parts that emit light of a first wavelength range and arranged in the first direction; and n second light control parts respectively spaced apart from the first light control parts in the second direction, and arranged in the first direction, the n second light control parts that emit light of a second wavelength range, wherein: a first dam opening may be defined between an (m+1)-th first light control part and an (m+2)-th first light control part; a second dam opening may be defined between an m-th second light control part and an (m+1)-th second light control part, n may be an integer greater than or equal to 1, and m may be an odd or even number.

In an embodiment, a first connection dam portion extending from first dam portions defining the first dam opening may be disposed between an (m+1)-th second light control part and an (m+2)-th second light control part, and a second connection dam portion extending from second dam portions defining the second dam opening may be disposed between an m-th first light control part and an (m+1)-th first light control part.

In an embodiment, the dam opening may be defined as a space between the plurality of dam portions disposed to be spaced apart from each other and side surfaces of the connection dam portions adjacent to the plurality of dam portions, and the shape of the dam opening in a plan view may have a polygonal shape including side surfaces of the plurality of dam portions defining the dam opening, the side surfaces of the connection dam portions, and edge surfaces of the plurality of light control parts adjacent to the side surfaces of the plurality of dam portions.

In an embodiment, the first barrier rib portions, the second barrier rib portions, and the plurality of dam portions may be formed on a same layer.

In an embodiment, an opening may be defined by the plurality of first barrier rib portions, the plurality of second barrier rib portions, and the plurality of dam portions, and the plurality of light control parts may be disposed in the opening.

In an embodiment, the plurality of dam portions may be disposed adjacent to a central portion of a length of the light control part in the first direction.

In an embodiment, the opening may include: a main opening defined between the plurality of first barrier rib portions spaced apart from each other in the second direction, wherein the plurality of light control parts may be disposed between the plurality of first barrier rib portions; and a dam opening defined between the plurality of second barrier rib portions and the plurality of dam portions spaced apart from each other in the second direction, wherein the plurality of light control parts may be disposed between the plurality of first barrier rib portions.

In an embodiment, the shape of the opening in a plan view may be a polygon including a portion in which a width of the dam opening in the second direction is greater than a width of the main opening in the second direction.

In an embodiment, the light control member may further include a base substrate and a color filter layer including a plurality of filter portions that transmit light of different wavelengths, and the plurality of light control parts may be disposed between the display panel and the color filter layer, and the color filter layer may be disposed between the plurality of light control parts and the base substrate.

In an embodiment, the division pattern layer may include a lower pattern layer including the plurality of first barrier rib portions and the plurality of second barrier rib portions and an upper pattern layer disposed on the lower pattern layer and including the plurality of dam portions, wherein a thickness of the upper pattern layer may correspond to a distance between the display panel and the lower pattern layer.

In an embodiment, the display device may further include a color filter layer including a plurality of filter portions that transmit light of different wavelengths, and the plurality of light control parts may be disposed directly on the display panel, wherein the color filter layer may be disposed above the plurality of light control parts.

In an embodiment, a display device may include: first, second, third, and fourth pixel regions that emit light of different wavelength ranges; a display element layer that provides source light; and a light control layer disposed on the display element layer and including a plurality of light control parts and a division pattern layer dividing the plurality of light control parts, wherein the division pattern layer may include: a lower pattern layer including a plurality of first barrier rib portions extending in a first direction and spaced apart from each other in a second direction perpendicular to the first direction and a plurality of second barrier rib portions extending in the second direction and spaced apart from each other in the first direction; and an upper pattern layer disposed on the lower pattern layer and including a plurality of dam portions spaced apart from each other in the second direction, a distance between the plurality of dam portions neighboring each other in the second direction is greater than a distance between the plurality of first barrier rib portions neighboring each other in the second direction.

In an embodiment, an opening defined by the plurality of first barrier rib portions and the plurality of second barrier rib portions may be disposed in the lower pattern layer, and a dam opening defined by the plurality of dam portions may be disposed in the upper pattern layer.

In an embodiment, the plurality of light control parts may be disposed in the opening, and a remaining light control part may be disposed in the dam opening, the remaining light control part and the plurality of light control parts adjacent to the dam opening that emit light of a same wavelength range.

In an embodiment, the plurality of light control parts may include: a plurality of first light control parts disposed to be arranged in the first direction and that emit red light; a plurality of second light control parts spaced apart from the first light control parts in the second direction, disposed to be arranged in the first direction, and that emit green light; a plurality of third light control parts spaced apart from the second light control parts in the second direction, disposed to be arranged in the first direction, and that emit blue light; and a plurality of fourth light control parts spaced apart from the third light control parts in the second direction, disposed to be arranged in the first direction, and that emit white light, wherein the first, second, third, and fourth light control parts may be respectively disposed in the openings.

In an embodiment, the plurality of first light control parts may include a first quantum dot that converts the source light into red light, the plurality of second light control parts may include a second quantum dot that converts the source light into green light, the plurality of third light control parts may not include a quantum dot, and the plurality of fourth light control parts may include the first quantum dot or both the first quantum dot and the second quantum dot.

In an embodiment, the display device may further include a color filter layer including first, second, third, and fourth filter portions respectively disposed to correspond to the first, second, third, and fourth pixel regions.

In an embodiment, the display device may further include a light blocking pattern layer that divides the first, second, third, and fourth pixel regions.

In another embodiment, a method for manufacturing a display device may include: providing a base member; forming, on the base member, a division pattern layer including a plurality of first barrier rib portions extending in a first direction and spaced apart from each other by a first distance in a second direction perpendicular to the first direction, a plurality of second barrier rib portions extending in the second direction, and a plurality of dam portions disposed to have a second distance greater than the first distance in the second direction; providing an initial printing resin including unreacted monomer to openings defined by the first barrier rib portions and the second barrier rib portions and dam openings defined by the plurality of dam portions; providing an ink composition on the provided initial printing resin; curing the ink composition; and removing the initial printing resin to form a light control member including light control parts.

In an embodiment, the providing of the initial printing resin and the providing of the ink composition may be performed by an inkjet printing method.

In an embodiment, the ink composition may include a base monomer having a polymerization reacting group, and the unreacted monomer may be formed by removing the polymerization reacting group from the base monomer.

In an embodiment, the unreacted monomer may have a vapor pressure of about 10⁻⁶ mmHg to about 10⁻¹ mmHg.

In an embodiment, the initial printing resin may further include an organic solvent having a vapor pressure of about 1 mmHg or less.

In an embodiment, the base member may include a base substrate and a color filter layer disposed on the base substrate, and the division pattern layer may be formed on a surface of the color filter layer.

In an embodiment, the method may further include: providing a display panel including a display element layer; and assembling the light control member and the display panel together.

In an embodiment, the base member may be a display panel including a display element layer, and the division pattern layer may be formed directly on the display panel.

### BRIEF DESCRIPTION OF THE DRAWINGS

The accompanying drawings are included to provide a further understanding of the invention, and are incorporated in and constitute a part of the description. The drawings illustrate embodiments and, together with the description, serve to explain principles of the invention. In the drawings:

FIG. 1 is a schematic perspective view of a display device according to an embodiment;

FIG. 2 is a schematic plan view of the display device according to an embodiment;

FIG. 3 is a schematic cross-sectional view of the display device according to an embodiment;

FIG. 4 is a schematic plan view of a light control member according to an embodiment;

FIG. 5 is a schematic cross-sectional view of a portion of the light control member according to an embodiment;

FIG. 6 is a schematic cross-sectional view of a portion of the light control member according to an embodiment;

FIG. 7 is a schematic plan view of the light control member according to an embodiment;

FIG. 8 is a schematic plan view of a portion of the light control member according to an embodiment;

FIG. 9 is a schematic cross-sectional view of the display device according to an embodiment;

FIG. 10 is a schematic plan view of a light control member according to an embodiment;

FIG. 11 is a schematic cross-sectional view of a portion of the light control member according to an embodiment;

FIG. 12 is a schematic cross-sectional view of a portion of the light control member according to an embodiment;

FIG. 13 is a schematic plan view of a light control member according to an embodiment;

FIG. 14 is a schematic cross-sectional view of a portion of the light control member according to an embodiment;

FIG. 15 is a schematic cross-sectional view of a portion of the light control member according to an embodiment;

FIG. 16 is a schematic plan view of a light control member according to an embodiment;

FIG. 17 is a schematic plan view of a display device according to an embodiment;

FIG. 18 is a schematic cross-sectional view of a display device according to an embodiment;

FIG. 19 is a flowchart of a method of manufacturing a display device according to an embodiment; and

Each of FIGS. 20A, 20B, 20C, 21A, 21B, 21C, 22A, 22B, 22C, 23A, 23B, 23C, 24A, 24B, and 24C schematically illustrates a step of the method of manufacturing the display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, a display device according to an embodiment and a method of manufacturing the display device according to an embodiment will be described with reference to the accompanying drawings.

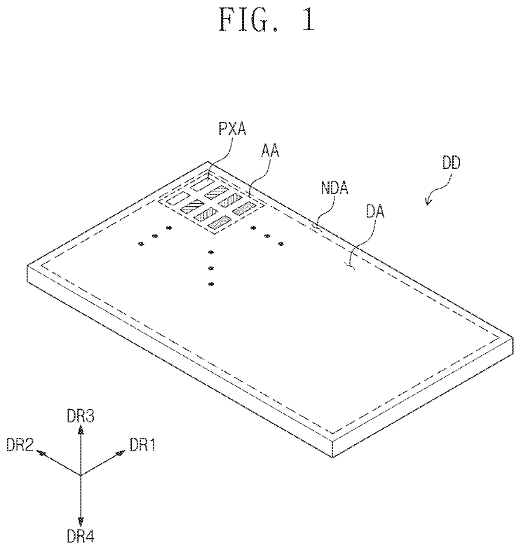

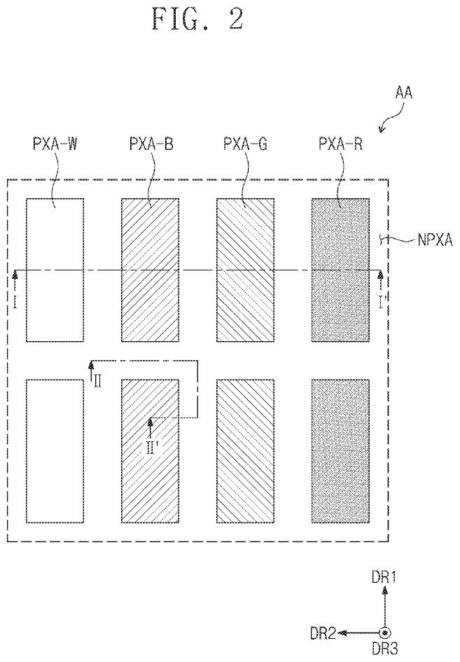

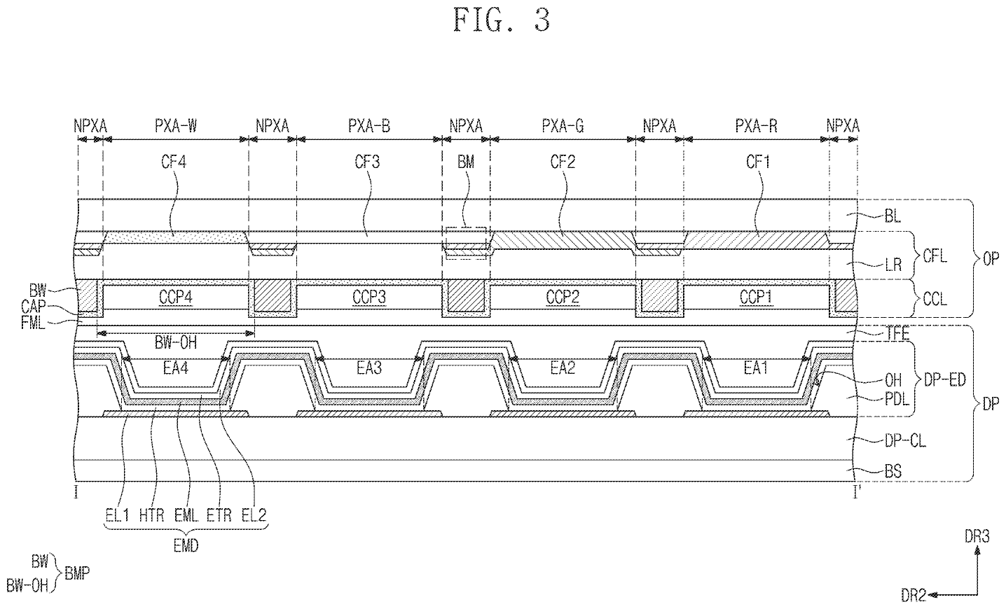

FIG. 1 is a schematic perspective view of a display device according to an embodiment. FIG. 2 is a schematic plan view of the display device according to an embodiment. FIG. 3 is a schematic cross-sectional view of the display device according to an embodiment. FIG. 2 is a schematic plan view illustrating a portion corresponding to a region AA of FIG. 1, and FIG. 3 is a schematic cross-sectional view taken along line I-I′ of FIG. 2.

The display device DD according to an embodiment may be activated according to an electrical signal. For example, the display device DD may be a mobile phone, a tablet, a car navigation system, a game machine, or a wearable device, but embodiments are not limited thereto.

For example, FIG. 1 and the following drawings illustrate first to fourth direction axes DR1 to DR4, and directions indicated by the first to fourth direction axes DR1, DR2, DR3, and DR4 described herein are relative concepts and may be converted to other directions. For example, the directions indicated by the first to fourth direction axes DR1, DR2. DR3, and DR4 may be described as first to fourth directions for which the same reference numerals may be used.

In the description, the thickness direction of the display device DD may be parallel to the third direction axis DR3 which is a normal direction of a plane defined by the first and second direction axes DR1 and DR2. The direction of the fourth direction axis DR4 may be defined as a direction opposite to the direction of the third direction axis DR3. In the description, the front surface (or upper surface) and rear surface (or lower surface) of members constituting the display device DD may be defined based on the third direction axis DR3.

The display device DD according to an embodiment may include a display region DA and a non-display region NDA adjacent to the display region DA. The display region DA may correspond to a portion in which an image is displayed. Pixel regions PXA may be disposed in the display region DA. The pixel regions PXA may be repeatedly disposed in the entire display region DA.

In an embodiment, the pixel regions PXA may include a first pixel region PXA-R, a second pixel region PXA-G, and a third pixel region PXA-B that are separated from each other. In an embodiment, the pixel regions PXA may further include a fourth pixel region PXA-W in addition to the first to third pixel regions PXA-R. PXA-G, and PXA-B. The first pixel region PXA-R, the second pixel region PXA-G, the third pixel region PXA-B, and the fourth pixel region PXA-W may emit light of different wavelength ranges. For example, in an embodiment, the first pixel region PXA-R may be a red light-emitting region that emits red light, the second pixel region PXA-G may be a green light-emitting region that emits green light, the third pixel region PXA-B may be a blue light-emitting region that emits blue light, and the fourth pixel region PXA-W may be a white light-emitting region that emits white light. In the description, the first pixel region PXA-R, the second pixel region PXA-G, the third pixel region PXA-B, and the fourth pixel region PXA-W may be respectively referred to as a red pixel region, a green pixel region, a blue pixel region, and a white pixel region. However, embodiments are not limited thereto, and the pixel regions PXA-R. PXA-G, PXA-B, and PAX-W may include a combination of pixel regions that emit other colors in addition to the red, green, blue, and white colors described above.

The first to fourth pixel regions PXA-R. PXA-G, PXA-B, and PXA-W may be separated from each other without overlapping each other in a plan view. A peripheral region NPXA may be disposed around the first to fourth pixel regions PXA-R. PXA-G, PXA-B, and PXA-W. The peripheral region NPXA may define boundaries between the first to fourth pixel regions PXA-R. PXA-G, PXA-B, and PXA-W. The peripheral region NPXA may surround each of the first to fourth pixel regions PXA-R. PXA-G, PXA-B, and PXA-W. In the peripheral region NPXA, a structure preventing color mixing between the first to fourth pixel regions PXA-R. PXA-G, PXA-B, and PXA-W, for example, a pixel defining film PDL, a division pattern layer BMP or the like may be disposed correspondingly. For example, although the first to fourth pixel regions PXA-R. PXA-G, PXA-B, and PXA-W finally recognized on the front surface of the display device DD may not be separated from each other by the division pattern layer BMP or the like, pixel regions may be separated from each other by a printed layer such as a black matrix defining the peripheral region NPXA or a stacked structure having a light blocking function.

Referring to FIG. 2, each of the first to fourth pixel regions PXA-R, PXA-G, PXA-B, and PXA-W may have a tetragonal shape in a plan view. However, embodiments are not limited thereto, and the first to fourth pixel regions PXA-R. PXA-G, PXA-B, and PXA-W may have a different polygonal shape (including a substantially polygonal shape) such as a rhombus or a pentagon in a plan view. The first to fourth pixel regions PXA-R. PXA-G. PXA-B, and PXA-W may have a rectangular shape (a substantially rectangular shape) with rounded corners in a plan view.

FIGS. 1 and 2 illustrate the display device DD including the first to fourth pixel regions PXA-R, PXA-G, PXA-B, and PXA-W having a same planar shape and a similar planar area, but embodiments are not limited thereto. An area of at least one type of pixel region among the first to fourth pixel regions PXA-R. PXA-G, PXA-B, and PXA-W may be different from those of the other types of pixel regions. The areas (or sizes) of the first to fourth pixel regions PXA-R, PXA-G, PXA-B, and PXA-W may be set according to light-emitting colors.

In the display device DD according to an embodiment, the pixel regions PXA-R. PXA-G, PXA-B, and PXA-W may be arranged in a stripe shape. Referring to FIGS. 1 and 2, each of first pixel regions PXA-R, second pixel regions PXA-G, third pixel regions PXA-B, and fourth pixel regions PXA-W may be aligned/arranged along the first direction DR1. For example, the first pixel region PXA-R, the second pixel region PXA-G, the third pixel region PXA-B, and the fourth pixel region PXA-W may be arranged alternately in the order named along the second direction DR2. For example, in the display device DD according to an embodiment, same pixel regions that emit light of a same light-emitting wavelength may be arranged along the first direction DR1, and different pixel regions that emit light of different light-emitting wavelengths may be repeatedly arranged in a certain order along the second direction DR2.

Referring to FIG. 3, the display device DD according to an embodiment may include a display panel DP and a light control member OP disposed on the display panel DP. In an embodiment, a filling layer FML may be disposed between the display panel DP and the light control member OP.

In an embodiment, the display panel DP may include a base layer BS, a circuit layer DP-CL disposed on the base layer BS, and a display element layer DP-ED disposed on the circuit layer DP-CL. For example, the display panel DP may include an encapsulation layer TFE disposed on the display element layer DP-ED. The display element layer DP-ED may include a pixel defining film PDL and a light-emitting element EMD. The encapsulation layer TFE may cover the upper portion of the display element layer DP-ED. The display element layer DP-ED may include light-emitting regions EA1, EA2, EA3, and EA4. Each of the light-emitting regions EA1, EA2, EA3, and EA4 of the display element layer DP-ED may correspond to each of the pixel regions PXA-R, PXA-G, PXA-B, and PXA-W of the display device DD.

In the display device DD according to an embodiment, the display panel DP may be a light-emitting display panel. For example, the display panel DP may be an organic electroluminescence display panel.

In case that the display panel DP is an organic electroluminescence display panel, the display element layer DP-ED may include an organic electroluminescence element as a light-emitting element EMD. However, embodiments are not limited thereto. For example, the display element layer DP-ED may include a quantum dot light-emitting diode as a light-emitting element EMD. For example, the display element layer DP-ED may include a micro LED element and/or a nano LED element as a light-emitting element EMD. The light-emitting element EMD may generate source light. The source light generated and output from the light-emitting element EMD may be provided to the light control member OP, and the source light may be converted into light of a different wavelength in a light control layer CCL of the light control member OP, or the source light may be scattered and transmitted.

In the display panel DP, the base layer BS may be a member that provides a base surface on which the display element layer DP-ED is disposed. The base layer BS may be a glass substrate, a metal substrate, or a polymer substrate. However, embodiments are not limited thereto, and the base layer BS may be an inorganic layer, a functional layer, or a composite material layer.

The base layer BS may have a multi-layered structure. For example, the base layer BS may have a three-layer structure of a polymer resin layer, an adhesive layer, and a polymer resin layer. For example, the polymer resin layer may include a polyimide-based resin. For example, the polymer resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In the description, a “˜˜”-based resin means to include a functional group of “˜˜”.

The circuit layer DP-CL may be disposed on the base layer BS. The circuit layer DP-CL may include an insulating layer, a semiconductor pattern layer, a conductive pattern layer, a signal line, and the like. An insulating layer, a semiconductor layer, and a conductive layer may be formed on the base layer BS by a method such as coating or deposition, and then, the insulating layer, the semiconductor layer, and the conductive layer may be selectively patterned by photolithography processes. Hereafter, a semiconductor pattern layer, a conductive pattern layer, and a signal line included in the circuit layer DP-CL may be formed. In an embodiment, the circuit layer DP-CL may include a transistor, a buffer layer, and insulating layers.

Referring to FIG. 3, the light-emitting element EMD according to an embodiment may include a first electrode EL1, a second electrode EL2 facing the first electrode EL1, and a light-emitting layer EML disposed between the first electrode EL1 and the second electrode EL2. The light-emitting layer EML included in the light-emitting element EMD may include an organic light-emitting material or a quantum dot as a light-emitting material. The light-emitting element EMD may further include a hole control layer HTR and an electron control layer ETR. For example, the light-emitting element EMD may further include a capping layer disposed on the second electrode EL2.

In an embodiment, the light-emitting element EMD may emit light in a blue light-emitting region as source light. In another example, the light-emitting element EMD may emit light in a visible light region ranging from about 480 nm to about 780 nm as source light.

The pixel defining film PDL may be disposed on the circuit layer DP-CL and cover a portion of the first electrode EL1. A light-emitting opening OH may be defined in the pixel defining film PDL. The light-emitting opening OH of the pixel defining film PDL may expose at least a portion of the first electrode EL1. In an embodiment, the light-emitting regions EA1, EA2, EA3, and EA4 may be defined to correspond to a partial region of the first electrode EL1 exposed by the light-emitting opening OH.

In the light-emitting element EMD, the first electrode EL1 may be disposed on the circuit layer DP-CL. The first electrode EL1 may be an anode or a cathode. For example, the first electrode EL1 may be a pixel electrode. The first electrode EL1 may be a transmissive electrode, a semi-transmissive electrode, or a reflective electrode.

The hole control layer HTR may be disposed between the first electrode EL1 and the light-emitting layer EML. The hole control layer HTR may include at least one of a hole injection layer, a hole transport layer, or an electron blocking layer. The hole control layer HTR may be disposed as a common layer so as to overlap (e.g., entirely overlap) the light-emitting regions EA1, EA2, EA3, and EA4 and the pixel defining film PDL dividing the light-emitting regions EA1, EA2, EA3, and EA4. However, embodiments are not limited thereto, and the hole control layer HTR may be patterned and provided so as to be separately disposed to correspond to each of the light-emitting regions EA1, EA2, EA3, and EA4.

The light-emitting layer EML may be disposed on the hole control layer HTR. In an embodiment, the light-emitting layer EML may be provided as a common layer so as to overlap (e.g., entirely overlap) the light-emitting regions EA1, EA2, EA3, and EA4 and the pixel defining film PDL dividing the light-emitting regions EA1, EA2, EA3, and EA4. In an embodiment, the light-emitting layer EML may emit blue light. In the display device DD according to an embodiment, blue light may be source light.

The light-emitting layer EML may overlap (e.g., entirely overlap) the hole control layer HTR and the electron control layer ETR. However, embodiments are not limited thereto, and in an embodiment, the light-emitting layer EML may be disposed in the light-emitting opening OH. For example, the light-emitting layer EML may be separately formed to correspond to the light-emitting regions EA1, EA2, EA3, and EA4 divided by the pixel defining film PDL. The light-emitting layer EML separately formed to correspond to the light-emitting regions EA1, EA2, EA3, and EA4 may emit light of a same wavelength range in each of the light-emitting regions EA1, EA2, EA3, and EA4, or the light-emitting layer EML may emit light of different wavelength ranges in each of the light-emitting regions EA1, EA2, EA3, and EA4.

The light-emitting layer EML may have a single-layered structure made of a single material, a single-layered structure made of different materials, or a multi-layered structure having a plurality of layers made of different materials. The light-emitting layer EML may include a fluorescent or phosphorescent material. In the light-emitting element EMD according to an embodiment, the light-emitting layer EML may include an organic light-emitting material, a metal organic complex, a quantum dot, or the like as a light-emitting material.

The electron control layer ETR may be disposed between the light-emitting layer EML and the second electrode EL2. The electron control layer ETR may include at least one of an electron injection layer, an electron transport layer, or a hole blocking layer. Referring to FIG. 3, the electron control layer ETR may be disposed as a common layer so as to overlap (e.g., entirely overlap) the light-emitting regions EA1, EA2, EA3, and EA4 and the pixel defining film PDL dividing the light-emitting regions EA1, EA2, EA3, and EA4. However, embodiments are not limited thereto, and the electron control layer ETR may be patterned and provided so as to be separately disposed to correspond to each of the light-emitting regions EA1. EA2, EA3, and EA4.

The second electrode EL2 may be provided on the electron control layer ETR. The second electrode EL2 may be a common electrode. The second electrode EL2 may be a cathode or an anode, but embodiments are not limited thereto. For example, in case that the first electrode EL1 is an anode, the second electrode EL2 may be a cathode, and in case that the first electrode EL1 is a cathode, the second electrode EL2 may be an anode. The second electrode EL2 may be a transmissive electrode, a semi-transmissive electrode, or a reflective electrode.

The encapsulation layer TFE may be disposed on the light-emitting element EMD. For example, in an embodiment, the encapsulation layer TFE may be disposed on the second electrode EL2. For example, in case that the light-emitting element EMD includes a capping layer, the encapsulation layer TFE may be disposed on the capping layer. The encapsulation layer TFE may include at least one organic layer and at least one inorganic layer, and the inorganic layer and the organic layer may be alternately disposed. The encapsulation layer TFE may function to protect the display element layer DP-ED from moisture/oxygen and prevent foreign substances such as dust particles from entering or permeating.

The encapsulation layer TFE may include at least one inorganic layer including at least one of silicon nitride, silicon oxynitride, or silicon oxide. For example, the inorganic layer may include titanium oxide or aluminum oxide.

The encapsulation layer TFE may include an organic layer disposed between inorganic layers. The organic layer may include an organic polymer material formed from an acrylate-based resin or the like. However, embodiments are not limited thereto.

The display device DD according to an embodiment may include a light control member OP disposed on the display panel DP and including a light control layer CCL. In an embodiment, the light control member OP may further include a base substrate BL and a color filter layer CFL.

The light control layer CCL may include a photoconverter. The photoconverter may be a quantum dot, a phosphor, or the like. The photoconverter may convert the wavelength of received light and emit the converted light. For example, the light control layer CCL may be a layer including a quantum dot or a phosphor.

The light control layer CCL may include light control parts CCP1, CCP2, CCP3, and CCP4. The light control parts CCP1, CCP2, CCP3, and CCP4 may be spaced apart from each other. The light control parts CCP1, CCP2, CCP3, and CCP4 may be spaced apart from each other by a division pattern layer BMP. The light control parts CCP1, CCP2, CCP3, and CCP4 may be disposed in an opening BW-OH defined in the division pattern layer BMP. However, embodiments are not limited thereto, and although FIG. 3 illustrates that the division pattern layer BMP does not overlap the light control parts CCP1, CCP2, CCP3, and CCP4, the edge portions of the light control parts CCP1, CCP2, CCP3, and CCP4 may at least partially overlap the division pattern layer BMP.

The light control parts CCP1, CCP2, CCP3, and CCP4 may convert the wavelength of light provided from the display element layer DP-ED or transmit the provided light. The light control parts CCP1, CCP2, CCP3, and CCP4 may be formed by an inkjet printing method. A liquid ink composition may be provided in the opening BW-OH, and the provided ink composition may be polymerized by a thermal curing process or a light curing process to form the light control parts CCP1, CCP2, CCP3, and CCP4.

The light control layer CCL may include: a first light control part CCP1 including first quantum dots that convert a first color light, which is source light, into a second color light; a second light control part CCP2 including second quantum dots that convert the first color light into a third color light; and a third light control part CCP3 that transmits the first color light. For example, the light control layer CCL may include a fourth light control part CCP4 which emits a fourth color light and may include a small amount of first quantum dots or both the first quantum dots and the second quantum dots, or may not include quantum dots.

In the display device DD according to an embodiment, the light-emitting element EMD may provide a first color light. For example, the first color light may be blue light. In the light control layer CCL according to an embodiment, the first light control part CCP1 may include red quantum dots that convert the first color light provided from the light-emitting element EMD into red light that is a second color light, and the second light control part CCP2 may include green quantum dots that convert the first color light provided from the light-emitting element EMD into green light that is a third color light.

The third light control part CCP3 may transmit the first color light provided from the light-emitting element EMD and may not include quantum dots. The fourth light control part CCP4 may emit white light, which is the fourth color light. The fourth light control part CCP4 may include a small amount of red quantum dots. For example, the fourth light control part CCP4 may include both red quantum dots and green quantum dots. For example, the fourth light control part CCP4 may be provided in a form in which a sub-light control part including red quantum dots and a sub-light control part including green quantum dots are stacked.

In the description, a quantum dot means a crystal of a semiconductor compound. The quantum dot may emit light of various light-emitting wavelengths according to the size of the crystal thereof. The quantum dot may emit light of various light-emitting wavelengths by adjusting the ratio of elements in a quantum dot compound.

The diameter of the quantum dot may be, for example, about 1 nm to about 10 nm. The quantum dot may be synthesized by a wet chemical process, a metal organic chemical vapor deposition (MOCVD) process, a molecular beam epitaxy (MBE) process, or a process similar thereto.

The wet chemical process may be a method of mixing an organic solvent with a precursor material and then growing a quantum dot particle crystal. In case that the crystal grows, the organic solvent naturally may function as a dispersant coordinated to the surface of the quantum dot crystal and control the growth of the crystal. Therefore, the wet chemical process may be easier than a vapor deposition process such as a metal organic chemical vapor deposition (MOCVD) process or a molecular beam epitaxy (MBE) process and control the growth of a quantum dot particle through a low-cost process.

The quantum dot may include: a group III-VI semiconductor compound; a group II-VI semiconductor compound; a group III-V semiconductor compound; a group II-IV-V semiconductor compound; a group I-III-VI semiconductor compound; a group IV-VI semiconductor compound; a group IV element or compound; or any combination thereof.

Examples of the group II-VI semiconductor compound may include: binary compounds such as CdS, CdSe, CdTe, ZnS, ZnSe, ZnTe, ZnO, HgS, HgSe, HgTe, MgSe, and MgS; ternary compounds such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and MgZnS; quaternary compounds such as CdZnSeS, CdZnSeTe, CdZnSTe, CdHgSeS, CdHgSeTe, CdHgSTe, HgZnSeS, HgZnSeTe, and HgZnSTe; or any combination thereof. For example, the group II-VI semiconductor compound may further include a group I metal and/or a group IV element. The group I-II-VI compound may be selected from CuSnS or CuZnS, and the group II-IV-VI compound may be selected from ZnSnS and the like. The group I-II-IV-VI compound may be selected from quaternary compounds selected from the group consisting of Cu₂ZnSnS₂, Cu₂ZnSnS₄, Cu₂ZnSnSe₄, Ag₂ZnSnS₂, and a mixture thereof.

Examples of the group III-V semiconductor compound may include: binary compounds such as GaN, GaP, GaAs, GaSb, AlN, AlP, AlAs, AlSb, InN, InP, InAs, and InSb; ternary compounds such as GaNP, GaNAs, GaNSb, GaPAs, GaPSb, AlNP, AlNAs, AlNSb, AlPAs, AlPSb, InGaP, InNP, InAlP, InNAs, InNSb, InPAs, and InPSb; quaternary compounds such as GaAlNP, GaAlNAs, GaAlNSb, GaAlPAs, GaAlPSb, GaInNP, GaInNAs, GaInNSb, GalnPAs, GaInPSb, InAlNP, InAlNAs, InAlNSb, InAlPAs, and InAlPSb; or any combination thereof. For example, the group III-V semiconductor compound may further include a group II element. Examples of the group III-V semiconductor compound further including the group II element may include InZnP, InGaZnP, InAlZnP, and the like.

Examples of the group III-VI semiconductor compound may include: binary compounds such as GaS, Ga₂S₃, GaSe, Ga₂Se₃, GaTe, InS, InSe, In₂Se₃, and InTe; ternary compounds such as InGaS₃, and InGaSe₃; or any combination thereof.

Examples of the group I-III-VI semiconductor compound may include: ternary compounds such as AgInS, AgInS₂, AgInSc₂, AgGaS, AgGaS₂, AgGaSe₂, CuInS, CuInS₂, CuInSe₂, CuGaS₂, CuGaSe₂, CuGaO₂, AgGaO₂, and AgAlO₂; quaternary compounds such as AgInGaS₂, and AgInGaSe₂; or any combination thereof.

Examples of the group IV-VI semiconductor compound may include: binary compounds such as SnS, SnSe, SnTe, PbS, PbSe, and PbTe; ternary compounds such as SnSeS, SnSeTe, SnSTe, PbSeS, PbSeTe, PbSTe, SnPbS, SnPbSe, and SnPbTe; quaternary compounds such as SnPbSSe, SnPbSeTe, and SnPbSTe; or any combination thereof.

Examples of the group II-IV-V semiconductor compound may include ternary compounds selected from the group consisting of ZnSnP, ZnSnP₂, ZnSnAs₂, ZnGeP₂. ZnGeAs₂, CdSnP₂, CdGeP₂ and a mixture thereof.

The group IV element or compound may include: unary compounds such as Si and Ge; binary compounds such as SiC and SiGe; or any combination thereof.

Each element included in the multi-element compounds such as the binary compounds, the ternary compounds, and the quaternary compounds may be present in a particle at a uniform concentration or at a non-uniform concentration. For example, the chemical formulas may mean types of elements included in the compounds, and the ratios of elements in the compounds may be different from each other. For example, AgInGaS₂ may mean AgInₓGa₁₋ₓS₂. Here x is a real number between 0 and 1.

For example, the quantum dot may have a single structure, in which the concentration of each element included in the corresponding quantum dot is uniform, or a dual core-shell structure. For example, a material included in a core and a material included in a shell may be different from each other.

The shell of the quantum dot may function as a protective layer for maintaining semiconductor properties by preventing chemical modification of the core and/or as a charging layer for imparting electrophoretic properties to the quantum dot. The shell may have a single layer or multiple layers. In the core/shell structure, the elements present in the shell may have a concentration gradient that decreases toward the core.

Examples of a quantum dot shell may include metal or non-metal oxide, a semiconductor compound, or a combination thereof. Examples of the metal or nonmetal oxide may include: binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO; ternary compounds such as MgAl₂O₄, CoFe₂O₄, NiFe₂O₄, and CoMn₂O₄; or any combination thereof. As described in the description, examples of the semiconductor compound may include a group III-VI semiconductor compound; a group II-VI semiconductor compound; a group III-V semiconductor compound; a group II-IV-V semiconductor compound; a group I-III-VI semiconductor compound; a group IV-VI semiconductor compound; or any combination thereof. For example, the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe. InAs, InP, InGaP, InSb, AlAs, AlP, AlSb, or any combination thereof.

Each element included in the multi-element compounds such as the binary compounds and the ternary compounds may be present in a particle at a uniform concentration or at a non-uniform concentration. For example, the chemical formulas may mean types of elements included in the compounds, and the ratios of elements in the compounds may be different from each other.

The quantum dot may have a full width of half maximum (FWHM) of a light-emitting wavelength spectrum of about 45 nm or less, e.g., about 40 nm or less, or more e.g., about 30 nm or less, and color purity or color reproducibility may be improved in those ranges. For example, since light emitted through such a quantum dot may be emitted in all directions, a wide viewing angle may be improved.

For example, the shape of the quantum dot may be specifically a spherical, pyramidal, multi-armed, or cubic nanoparticle, nanotube, nanowire, nanofiber, or nanoplate particle.

Since an energy band gap may be controlled by adjusting the size of the quantum dot or the ratio of elements in the quantum dot compound, light of various wavelengths may be generated from a quantum dot light-emitting layer. Therefore, by using the quantum dot described above (or by using quantum dots of different sizes or different element ratios in the quantum dot compound), a light-emitting element that emits light of various wavelengths may be implemented. For example, the control of the size of the quantum dot or the ratio of elements in the quantum dot compound may be selected so as to emit red, green and/or blue light. For example, the quantum dots may function to emit white light by combining light of various colors.

Each of the first to fourth light control parts CCP1, CCP2, CCP3, and CCP4 may further include scatterers. For example, the third light control part CCP3 may not include quantum dots, but may include scatterers.

The scatterer may be a particle having a refractive index different from that of a light-transmitting resin, for example, a light-scattering particle. The scatterer is not particularly limited as long as it is a material capable of partially scattering transmitted light by forming an optical interface with a base resin, and it may be, for example, a metal oxide particle or an organic particle. The scatterer may include, as metal oxide, titanium oxide (TiO₂), zirconium oxide (ZrO₂), aluminum oxide (Al₂O₃), indium oxide (In₂O₃), zinc oxide (ZnO), tin oxide (SnO₂), or the like. For example, the scatterer may include an acrylate-based resin or a urethane-based resin as an organic material. The scatterer may scatter light in various directions regardless of the incident angle of the light without substantially converting the wavelength of the incident light. Thus, side visibility may be improved.

Each of the first light control part CCP1, the second light control part CCP2, the third light control part CCP3, and the fourth light control part CCP4 may include a base resin for dispersing quantum dots or scatterers. In an embodiment, the first light control part CCP1 may include first quantum dots and scatterers dispersed in the base resin, the second light control part CCP2 may include second quantum dots and scatterers dispersed in the base resin, and the third light control part CCP3 may include scatterers dispersed in the base resin. The fourth light control part CCP4 may include first quantum dots and scatterers dispersed in the base resin, or may include first and second quantum dots and scatterers dispersed in the base resin.

The base resin may be a medium, in which quantum dots and scatterers are dispersed, and may be made of various resin compositions that may be generally referred to as binders. For example, the base resin may be an acrylic-based resin, a urethane-based resin, a silicone-based resin, an epoxy-based resin, and the like. The base resin may be a transparent resin.

The light control layer CCL may further include a barrier layer CAP disposed on at least one of the upper portion or the lower portion of the light control parts CCP1, CCP2, CCP3, and CCP4. The barrier layer CAP may function to prevent moisture and/or oxygen (hereinafter referred to as ‘moisture/oxygen’) from entering or permeating. In an embodiment illustrated in FIG. 3, the barrier layer CAP may be disposed above the light control parts CCP1, CCP2, CCP3, and CCP4 adjacent to the color filter layer CFL. In an embodiment, the barrier layer CAP may be disposed to cover the upper surfaces of the light control parts CCP1, CCP2, CCP3, and CCP4 and the division pattern layer BMP. However, embodiments are not limited thereto, and the barrier layer may be disposed below the light control parts CCP1. CCP2, CCP3, and CCP4 adjacent to the display panel DP to block the light control parts CCP1, CCP2, CCP3, and CCP4 from being exposed to moisture/oxygen.

The barrier layer CAP may include at least one inorganic layer. For example, the barrier layer CAP may include an inorganic material. For example, the barrier layer CAP may include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a thin metal film having a certain light transmittance. However, embodiments are not limited thereto, and the barrier layer CAP may further include an organic film. The barrier layer CAP may be formed as a single layer or a plurality of layers.

In the display device DD according to an embodiment, the light control member OP may include a color filter layer CFL disposed on the light control layer CCL. The color filter layer CFL may include filter portions CF1, CF2, CF3, and CF4. The color filter layer CFL may include a first filter portion CF1 that transmits a second color light, a second filter portion CF2 that transmits a third color light, a third filter portion CF3 that transmits a first color light, and a fourth filter portion CF4 that transmits a fourth color light. For example, the first filter portion CF1 may be a red filter, the second filter portion CF2 may be a green filter, the third filter portion CF3 may be a blue filter, and the fourth filter portion CF4 may be a white filter. In another example, the fourth filter portion CF4 may be omitted. In another example, the fourth filter portion CF4 may be formed of a transparent photosensitive resin.

Each of the first to third filter portions CF1, CF2, and CF3 may include a polymer photosensitive resin and a pigment or dye. The first filter portion CF1 may include a red pigment or dye, the second filter portion CF2 may include a green pigment or dye, and the third filter portion CF3 may include a blue pigment or dye. However, embodiments are not limited thereto, and the third filter portion CF3 may not include a pigment or dye. The third filter portion CF3 may include a polymeric photosensitive resin and may not include a pigment or dye. The third filter portion CF3 may be transparent. The third filter portion CF3 may be formed of a transparent photosensitive resin.

In an embodiment, the first filter portion CF1 and the second filter portion CF2 may be yellow filters. The first filter portion CF1 and the second filter portion CF2 may be integral with each other without being separated from each other. Each of the first to fourth filter portions CF1, CF2, CF3, and CF4 may be disposed to correspond to each of the first pixel region PXA-R, the second pixel region PXA-G, the third pixel region PXA-B, and the fourth pixel region PXA-W. For example, each of the first to fourth filter portions CF1, CF2, CF3, and CF4 may be disposed to correspond to each of the first to fourth light control parts CCP1, CCP2, CCP3, and CCP4.

For example, the filter portions CF1, CF2, and CF3 that transmit light of different colors may be disposed to overlap each other, while corresponding to the peripheral region NPXA disposed between the pixel regions PXA-R. PXA-G, PXA-B, and PXA-W. Since the filter portions CF1, CF2, and CF3 are disposed to overlap each other in the direction of the third direction axis DR3, which is the thickness direction, boundaries between the pixel regions PXA-R. PXA-G, PXA-B, and PXA-W adjacent to each other may be demarcated. A portion in which the filter portions CF1, CF2, and CF3 are disposed to overlap each other may be referred to as a light blocking pattern layer BM. For example, unlike what is illustrated, the color filter layer CFL may further include a separate light blocking layer which demarcates boundaries between the filter portions CF1, CF2, CF3, and CF4 adjacent to each other. For example, the light blocking layer may be included in the color filter layer CFL so as to overlap the peripheral region NPXA instead of the light blocking pattern layer BM in which the filter portions CF1, CF2, and CF3 are disposed to overlap each other. The light blocking layer may be formed of a blue filter or may be formed by including an organic light blocking material or an inorganic light blocking material including a black pigment or black dye.

In an embodiment, the light blocking pattern layer BM may be a portion corresponding to the peripheral region NPXA. The pixel regions PXA-R. PXA-G, PXA-B, and PXA-W may be divided and defined by the light blocking pattern layer BM, as illustrated in the plan view of FIG. 2, etc. In an embodiment, each of the pixel regions PXA-R. PXA-G, PXA-B, and PXA-W may be a portion corresponding to each of the light control parts CCP1. CCP2, CCP3, and CCP4.

However, embodiments are not limited thereto. For example, two first pixel regions PXA-R (see FIG. 2) adjacent to each other in the first direction DR1 (see FIG. 2) may be divided by the light blocking pattern layer BM, and therefore, the arrangement of the pixel regions may be illustrated as in FIG. 2. For example, the light control part CCP1 may be provided in an opening as in an embodiment illustrated in FIG. 13, etc. to be described below, and one first light control part CCP1 may correspond to two first pixel regions PXA-R neighboring each other. For example, the arrangement of the pixel regions PXA-R, PXA-G, PXA-B. and PXA-W shown in the display device DD according to an embodiment may be divided by the light blocking pattern layer BM, or by the division pattern layer BMP included in the light control layer CCL to be described below.

The color filter layer CFL may include a low refractive index layer LR. The low refractive index layer LR may be disposed between the light control layer CCL and the filter portions CF1, CF2, CF3, and CFL4. The low refractive index layer LR may be disposed on the light control layer CCL to block the light control parts CCP1. CCP2, CCP3, and CCP4 from being exposed to moisture/oxygen. For example, the low refractive index layer LR may be disposed between the light control parts CCP1, CCP2, CCP3, and CCP4 and the filter portions CF1, CF2, CF3, and CF4 to function as an optical functional layer that increases light extraction efficiency or to prevent reflected light from entering (or permeating) the light control layer CCL. The low refractive index layer LR may be a layer having a lower refractive index than an adjacent layer.

The low refractive index layer LR may include at least one inorganic layer. For example, the low refractive index layer LR may include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a thin metal film having a certain light transmittance. However, embodiments are not limited thereto, and the low refractive index layer LR may include an organic layer. For example, the low refractive index layer LR may be formed by including a polymer resin, an inorganic particle, and the like. The low refractive index layer LR may be formed as a single layer or a plurality of layers.

For example, in the display device DD according to an embodiment, the filter portions CF1, CF2, CF3, and CF4 of the color filter layer CFL may be disposed directly on the light control layer CCL. For example, the low refractive index layer LR may be omitted.

In an embodiment, the light control member OP may further include a base substrate BL disposed on the color filter layer CFL. The base substrate BL may be a member that provides a base surface on which the color filter layer CFL, the light control layer CCL, and the like are disposed. The base substrate BL may be a glass substrate, a metal substrate, a plastic substrate, or the like. However, embodiments are not limited thereto, and the base substrate BL may be an inorganic layer, an organic layer, or a composite material layer. In an embodiment, the base substrate BL may be omitted.

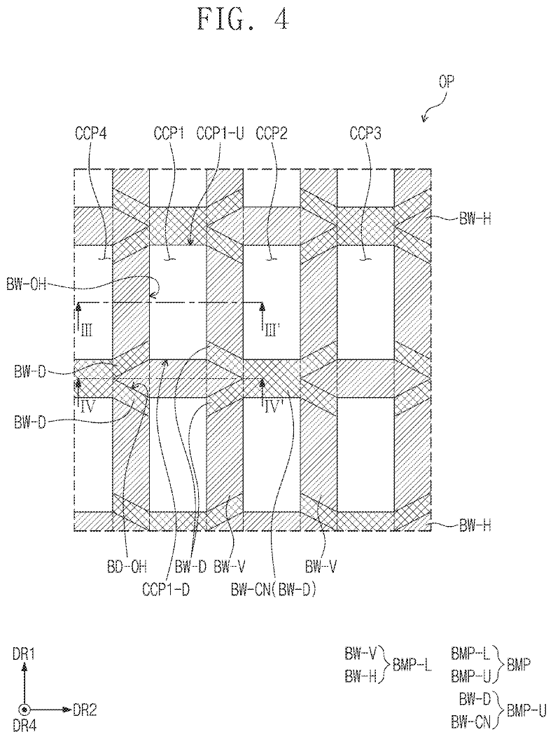

The light control layer CCL may include a division pattern layer BMP that divides the light control parts CCP1, CCP2, CCP3, and CCP4. As illustrated in FIG. 3, when viewed on a plane parallel to a plane defined by the second and third direction axes DR2 and DR3, the division pattern layer BMP that divides the light control parts CCP1, CCP2, CCP3, and CCP4 may include a barrier rib portion BW and an opening BW-OH. The light control parts CCP1, CCP2, CCP3, and CCP4 may be disposed in the opening BW-OH. In the light control layer CCL illustrated in FIG. 3, the barrier rib portion BW may be a portion corresponding to a first barrier rib portion BW-V (see FIG. 4, etc.) described in an embodiment of a light control member to be described below.

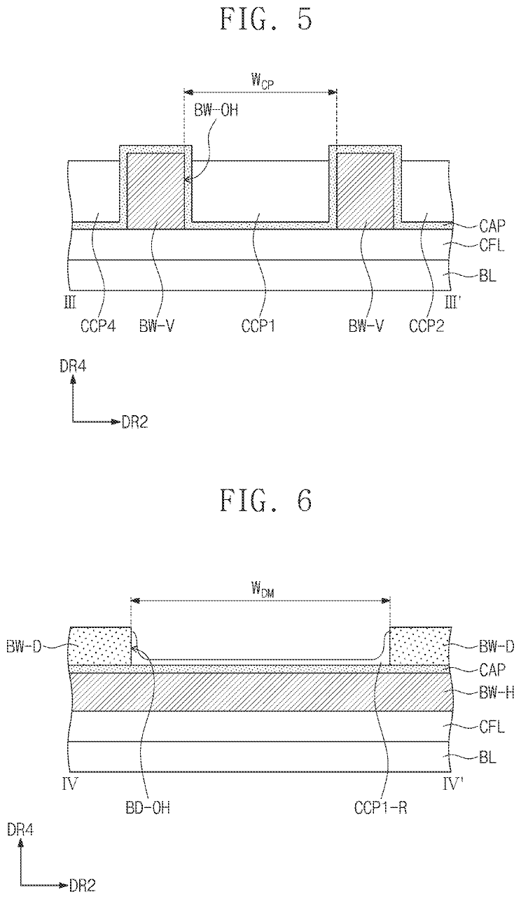

FIG. 4 is a schematic plan view illustrating a portion of a light control member according to an embodiment. Each of FIGS. 5 and 6 is a schematic cross-sectional view illustrating a portion of the light control member according to an embodiment. FIG. 5 is a schematic cross-sectional view taken along line III-III′ of FIG. 4, and FIG. 6 is a schematic cross-sectional view taken along line IV-IV′ of FIG. 4.

Referring to FIGS. 4 to 6, the light control member OP according to an embodiment may include light control parts CCP1, CCP2, CCP3, and CCP4 and a division pattern layer BMP that divides the light control parts CCP1, CCP2, CCP3, and CCP4.

In an embodiment, the division pattern layer BMP may include a first barrier rib portion BW-V, a second barrier rib portion BW-H, and a dam portion BW-D. For example, an opening BW-OH and a dam opening BD-OH may be defined in the division pattern layer BMP.

Referring to FIG. 4, in the light control member OP according to an embodiment, the first to fourth light control parts CCP1, CCP2, CCP3, and CCP4 may be sequentially arranged along the second direction DR2. For example, each of first light control parts CCP1, second light control parts CCP2, third light control parts CCP3, and fourth light control parts CCP4 may be arranged along the first direction DR1. For example, in an embodiment, in the light control parts CCP1, CCP2, CCP3, and CCP4 included in the light control member OP, a same type of light control parts that emit light of a same wavelength range along the first direction DR1 may be arranged in a row, and different types of light control parts that emit light of different wavelength ranges along the second direction DR2 may be arranged in a regular manner. In an embodiment, the light control parts CCP1, CCP2, CCP3, and CCP4 may be arranged in a stripe shape.

The division pattern layer BMP may include first barrier rib portions BW-V. Referring to FIG. 4, each of the first barrier rib portions BW-V may extend in a direction parallel to the first direction DR1, and adjacent first barrier rib portions BW-V may be spaced apart from each other in the second direction DR2.

The division pattern layer BMP may include second barrier rib portions BW-H. Referring to FIG. 4, each of the second barrier rib portions BW-H may extend in a direction parallel to the second direction DR2, and adjacent second barrier rib portions BW-H may be spaced apart from each other in the first direction DR1.

The first barrier rib portions BW-V and the second barrier rib portions BW-H may define openings BW-OH in which the light control parts CCP1, CCP2, CCP3, and CCP4 are disposed. In the descriptions of the light control parts and the division pattern layer with reference to the following drawings, the first light control part CCP1 and the division pattern layer BMP adjacent to the first light control part CCP1 will be described, and the descriptions of the first light control part CCP1 and the division pattern layer BMP adjacent thereto may be equally applied to the descriptions of the second to fourth light control parts CCP2, CCP3, and CCP4 and the division pattern layer BMP dividing them. Hereinafter, the first light control part CCP1 will be described as a representative light control part CCP1.

Referring to FIGS. 4 to 6, the first barrier rib portions BW-V may be disposed to be spaced apart from each other in the second direction DR2 with the light control part CCP1 interposed therebetween, and the second barrier rib portions BW-H may be disposed to be spaced apart from each other in the first direction DR1 with the light control part CCP1 interposed therebetween. The opening BW-OH may be defined by two first barrier rib portions BW-V disposed adjacent to each other and two second barrier rib portions BW-H disposed adjacent to each other. The light control part CCP1 may be disposed in the opening BW-OH.

The dam portion BW-D may be disposed between adjacent light control parts CCP1 in the first direction DR1 or at a central portion of a length of the light control part CCP1 in the first direction DR1. In the light control member OP according to an embodiment illustrated in FIGS. 4 to 6, the dam portion BW-D may be disposed adjacent to an upper end portion CCP1-U or a lower end portion CCP1-D of the light control part CCP1 spaced apart from each other in the first direction DR1 of the light control part CCP1.

The division pattern layer BMP may include a lower pattern layer BMP-L and an upper pattern layer BMP-U stacked in the direction of the fourth direction axis DR4. For example, the light control member OP according to an embodiment may include the division pattern layer BMP having a two-stage structure (or two-layered structure) in which two pattern layers are stacked.

In the division pattern layer BMP having the two-stage structure (or two-layered structure), the lower pattern layer BMP-L may include a first barrier rib portion BW-V and a second barrier rib portion BW-H. The first barrier rib portion BW-V and the second barrier rib portion BW-H constituting the lower pattern layer BMP-L may be disposed on the color filter layer CFL. For example, the color filter layer CFL may be disposed on the base substrate BL. The light control member OP according to an embodiment may include a base substrate BL, a color filter layer CFL, a lower pattern layer BMP-L, and an upper pattern layer BMP-U sequentially disposed in the direction of the fourth direction axis DR4.

The upper pattern layer BMP-U may include a dam portion BW-D. The dam portion BW-D of the upper pattern layer BMP-U may be disposed on the lower pattern layer BMP-L. Referring to FIG. 4, the dam portion BW-D may include a portion that is concavely recessed in a direction away from the light control part CCP1. When viewed on a plane defined by the first direction axis DR1 and the second direction axis DR2, the dam portion BW-D may have a “V” shape in which the edge portion of the letter “V” is directed toward a direction parallel to the second direction axis DR2. A space between two dam portions BW-D spaced apart from and facing each other in the second direction DR2 may be defined as a dam opening BD-OH. The dam opening BD-OH may be defined on the second barrier rib portion BW-H. The dam opening BD-OH may be defined between the light control parts CCP1 adjacent to each other in the first direction DR1.

On a plane defined by the first and second direction axes DR1 and DR2, the dam opening BD-OH may have a polygonal shape. In a plan view, the dam opening BD-OH may have a polygonal shape including a portion having a maximum separation distance W_{DM} between the dam portions BW-D spaced apart from each other in the second direction DR2. The dam opening BD-OH may be a portion defined by the dam portions BW-D spaced apart from each other in the second direction DR2 with the light control part CCP1 interposed therebetween and the edge portions of the light control parts CCP1 neighboring each other in the first direction DR1.

The barrier layer CAP included in the light control member OP may cover the lower pattern layer BMP-L defining the openings BW-OH. For example, the barrier layer CAP may cover the opening BW-OH. The light control part CCP1 may be disposed in the opening BW-OH covered by the barrier layer CAP.

Referring to FIGS. 4 to 6, a second distance (or second width) W_{DM} of the dam opening BD-OH in the second direction DR2 may be greater than a first distance (or first width) W_{CP} of the opening BW-OH in the second direction DR2. In an embodiment, the second distance W_{DM} between the dam portions BW-D spaced apart from each other in the second direction DR2 may be greater than the first distance W_{CP} between the first barrier rib portions BW-V spaced apart from each other in the second direction DR2.

The dam opening BD-OH may be defined by the dam portions BW-D, and the barrier layer CAP may be exposed, which covers the second barrier rib portion BW-H that is a portion of the lower pattern layer BMP-L in the dam opening BD-OH. A remaining light control part CCP1-R may be disposed in the dam opening BD-OH. The remaining light control part CCP1-R may be formed of the same material as the light control part CCP1 disposed in the opening BW-OH adjacent to the dam opening BD-OH in the first direction DR1.

The remaining light control part CCP1-R may be disposed on the barrier layer CAP exposed from the dam opening BD-OH. For example, the remaining light control part CCP1-R may be disposed in contact with a side surface of the dam portion BW-D defining the dam opening BD-OH. The remaining light control part CCP1-R may not be disposed on the upper surface of the dam portion BW-D. The dam portion BW-D may have liquid repellency, and accordingly, the remaining light control part CCP1-R may not spread to the upper surface of the dam portion BW-D and may be disposed only in the dam opening BD-OH.

For example, the arrangement of the remaining light control part CCP1-R is not limited to what is illustrated in FIG. 6, etc. The remaining light control part CCP1-R may be a portion formed by a remaining portion of ink composition provided in case that a neighboring light control part CCP1 is formed, and the remaining light control part CCP1-R may remain in a partial region in the dam opening BD-OH, or a side surface of the dam portion BW-D and the upper surface of the barrier layer CAP may be exposed from the dam opening BD-OH as the remaining light control part CCP1-R does not remain.

In an embodiment, the dam portions BW-D defining the dam opening BD-OH having a width in the second direction DR2 greater than a width of the openings BW-OH in the second direction DR2 may be disposed between adjacent openings BW-OH in the first direction DR1. By forming the light control parts CCP1 by additionally providing an ink composition to the dam opening BD-OH defined by the dam portions BW-D, it is possible to ensure a process margin for obtaining the print quality of the light control part CCP1 even in a high-resolution design having a small separation distance between the light control parts CCP1 and CCP2 in the second direction DR2.

In an embodiment, the upper pattern layer BMP-U may further include a connection dam portion BW-CN. The connection dam portion BW-CN may be disposed on the lower pattern layer BMP-L. The connection dam portion BW-CN may be a portion extending from the dam portion BW-D in the second direction DR2. The connection dam portion BW-CN may be disposed to overlap the second barrier rib portion BW-H. The dam portion BW-D and the connection dam portion BW-CN may be integral with each other.

The dam opening BD-OH disposed between the first light control parts CCP1 may overlap the connection dam portion BW-CN in the second direction DR2 which is disposed between the second light control parts CCP2 disposed to be spaced apart from the first light control parts CCP1 in the second direction DR2. The dam portion BW-D defining the dam opening BD-OH disposed between the first light control parts CCP1 may be connected to the connection dam portion BW-CN disposed between adjacent second light control parts CCP2. However, embodiments are not limited to what is illustrated in FIG. 4, etc., and the connection form of the dam portion BW-D and the connection dam portion BW-CN may be variously changed, and accordingly, the planar shape of the dam opening BD-OH may be changed.

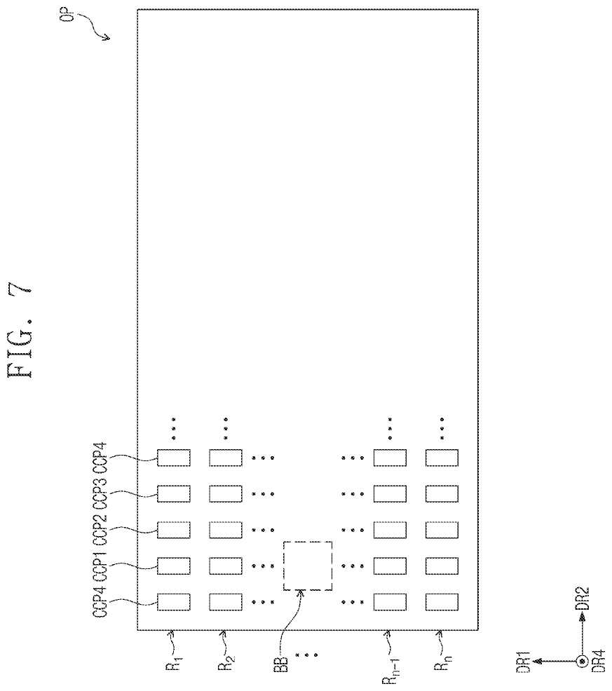

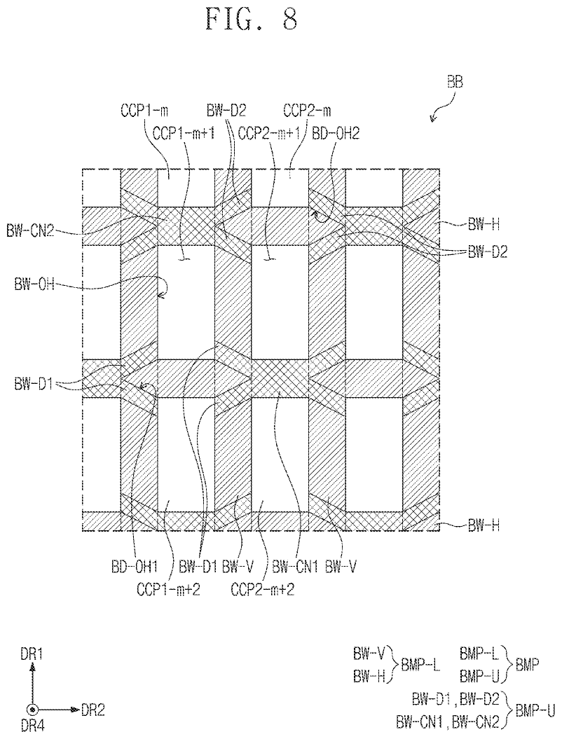

FIG. 7 is a schematic plan view of a light control member according to an embodiment, and FIG. 8 is a schematic plan view of a portion of the light control member according to an embodiment. FIG. 8 is a schematic plan view of a portion corresponding to a region BB of FIG. 7.

Referring to FIGS. 7 and 8, the light control member OP according to an embodiment may include n first light control parts CCP1 aligned/arranged in the first direction DR1, n second light control parts CCP2 aligned/arranged in the first direction DR1, n third light control parts CCP3 aligned/arranged in the first direction DR1, and n fourth light control parts CCP4 aligned/arranged in the first direction DR1. Each of the first to fourth light control parts CCP1, CCP2, CCP3, and CCP4 may be arranged to be spaced apart from each other in the first direction DR1. Each of the first to fourth light control parts CCP1, CCP2, CCP3, and CCP4 may be arranged to have n rows R1, R2, . . . , Rₙ₋₁, and Rₙ. Here, n is an integer greater than or equal to 1.

In an embodiment, the light control parts may be disposed in the second direction DR2 in the order of the first light control part CCP1, the second light control part CCP2, the third light control part CCP3, and the fourth light control part CCP4. The first to fourth light control parts CCP1, CCP2, CCP3, and CCP4 may emit light of different wavelength ranges.

The second light control parts CCP2 may be respectively spaced apart from the first light control parts CCP1 positioned in a same row in the second direction DR2. The first light control parts CCP1 may emit light of a first wavelength range, and the second light control parts CCP2 may emit light of a second wavelength range.

In an embodiment, the light control member OP may include first to fourth light control parts CCP1, CCP2, CCP3, and CCP4 and a division pattern layer BMP that divides the first to fourth light control parts CCP1. CCP2, CCP3, and CCP4. The division pattern layer BMP may include a first barrier rib portion BW-V, a second barrier rib portion BW-H, and dam portions BW-D1 and BW-D2.

Referring to FIGS. 7 and 8, in an embodiment, a first dam opening BD-OH1 may be defined between an (m+1)-th first light control part CCP1-m+1 and an (m+2)-th first light control part CCP1-m+2, and a second dam opening BD-OH2 may be defined between an m-th second light control part CCP2-m and an (m+1)-th second light control part CCP2-m+1. Here, m is an odd number or an even number. Here, m is an odd or even number and is smaller than n. The first dam opening BD-OH1 may be defined by the first dam portions BW-D1, and the second dam opening BD-OH2 may be defined by the second dam portions BW-D2.

Here, m is an odd number or an even number, and first dam openings BD-OH1 may be defined to be spaced apart from each other with two first light control parts CCP1 (see FIG. 7) arranged in the first direction DR1 and interposed therebetween, and second dam openings BD-OH2 may be defined to be spaced apart from each other with two second light control parts CCP2 (see FIG. 7) arranged in the first direction DR1 and interposed therebetween. For example, as m is increased to an odd number or an even number, the first dam openings BD-OH1 and the second dam openings BD-OH2 may be, respectively, repeatedly defined by a separation distance with two light control parts CCP1 and CCP2 (see FIG. 7) interposed therebetween. For example, the dam openings defined between the first light control parts and the second light control parts are illustrated and described in FIG. 8, etc., and the contents described above with reference to FIGS. 7 and 8 may be equally applied to the dam openings defined between the third light control parts and between the fourth light control parts.

The light control member OP according to an embodiment may include a first connection dam portion BW-CN1 extending from the first dam portions BW-D1 and a second connection dam portion BW-CN2 extending from the second dam portions BW-D2. The first connection dam portion BW-CN1 may be disposed between an (m+1)-th second light control part CCP2-m+1 and an (m+2)-th second light control part CCP2-m+2, and the second connection dam portion BW-CN2 may be disposed between an m-th first light control part CCP1-m and an (m+1)-th first light control part CCP1-m+1.

In an embodiment, the first dam opening BD-OH1 and the second dam opening BD-OH2 may be defined to cross each other by one row difference without overlapping each other in the second direction DR2. Since the light control member OP according to an embodiment includes the first dam opening BD-OH1 and the second dam opening BD-OH2 disposed to cross each other, the light control parts may sufficiently fill the opening BW-OH in case that a separation distance between neighboring light control parts in the second direction DR2 is reduced, thus exhibiting/having excellent appearance quality.

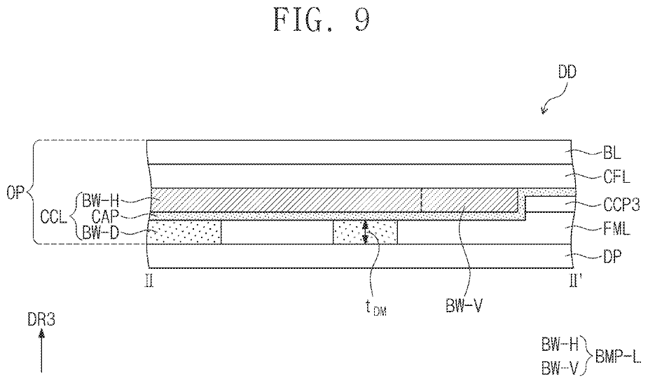

In the division pattern layer BMP having a two-stage structure (or a two-layered structure) and included in the light control member OP according to an embodiment illustrated in FIGS. 4 to 8, etc., the upper pattern layer BMP-U may function as a column spacer in the display device DD (see FIG. 1) according to an embodiment. FIG. 9 is a schematic cross-sectional view illustrating a portion of the display device according to an embodiment. FIG. 9 is a schematic cross-sectional view of a portion taken along line II-II′ of FIG. 2.

A thickness t_{DM} of the dam portion BW-D included in the upper pattern layer BMP-U may be about 0.1 μm to about 10 μm. The thickness t_{DM} of the dam portion BW-D may correspond to the maximum thickness of the filling layer FML that fills a space between the display panel DP and the light control member OP. However, embodiments are not limited thereto, and in an embodiment, the dam portion BW-D may be disposed between the lower pattern layer BMP-L and the display panel DP so that the display panel DP and the light control parts CCP3 may be spaced apart from each other by a certain distance. In an embodiment, as the display device DD includes the division pattern layer BMP (see FIG. 4) having a two-stage structure (or two-layered structure) without introducing a separate column spacer, it is possible to improve the print quality of the light control parts CCP1, CCP2, CCP3, and CCP4 (see FIG. 4) and maintain a gap between the display panel DP and the light control parts CCP1, CCP2, CCP3, and CCP4 (see FIG. 4), thus exhibiting/having good mechanical properties.

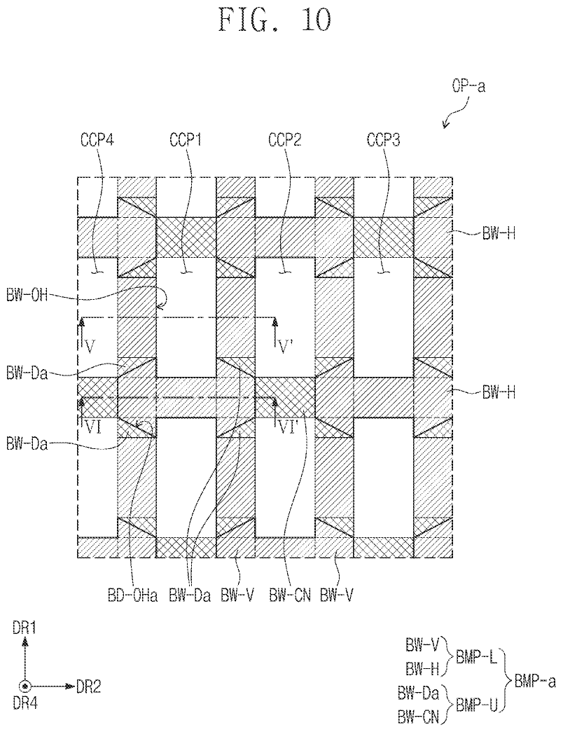

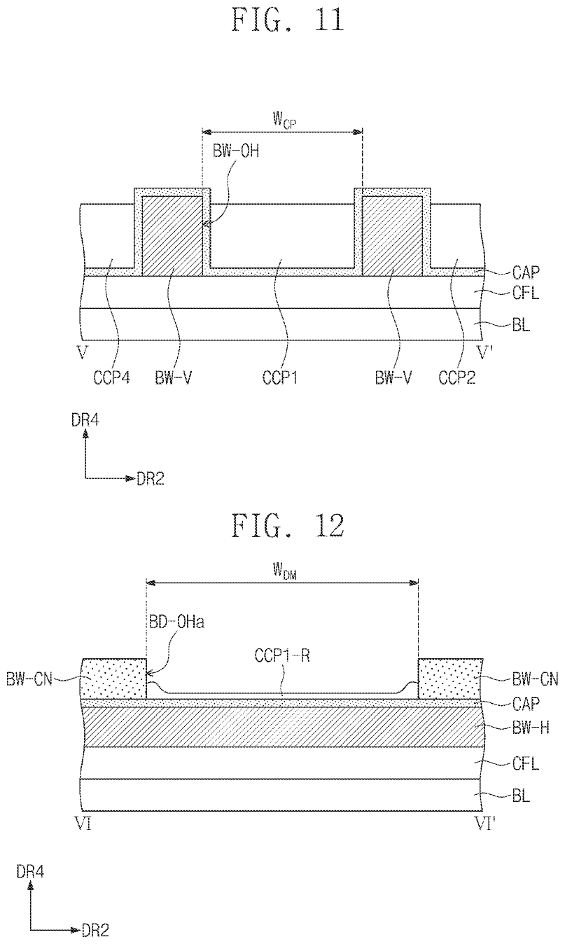

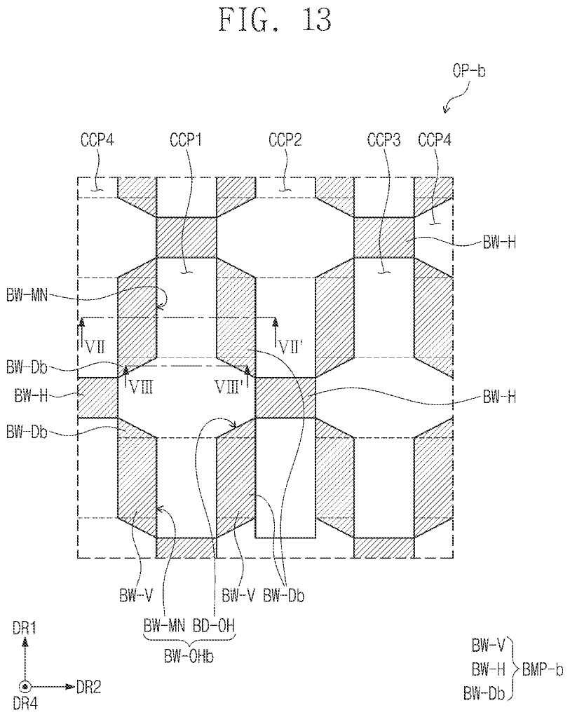

Hereinafter, a light control member according to an embodiment will be described with reference to FIGS. 10 to 17. In the descriptions of FIGS. 10 to 17, the contents overlapping those described above with reference to FIGS. 1 to 9 will not be described again for descriptive convenience, and differences will be described.

FIG. 10 is a schematic plan view of a light control member according to an embodiment. Each of FIGS. 11 and 12 is a schematic cross-sectional view of a portion of the light control member according to an embodiment. FIG. 11 is a schematic cross-sectional view of a portion taken along line V-V′ of FIG. 10, and FIG. 12 is a schematic cross-sectional view of a portion taken along line VI-VI′ of FIG. 10.

Referring to FIGS. 10 to 12, a light control member OP-a according to an embodiment may include light control parts CCP1, CCP2, CCP3, and CCP4 and a division pattern layer BMP-a including a first barrier rib portion BW-V, a second barrier rib portion BW-H, and a dam portion BW-Da. Hereinafter, in the description of the light control member OP-a, the first light control part CCP1 will be representatively described as an example of the light control part CCP1.

The first barrier rib portions BW-V may extend in the first direction DR1 and be disposed to be spaced apart from each other in the second direction DR2 with the light control part CCP1 interposed therebetween. The second barrier rib portions BW-H may extend in the second direction DR2 and be disposed to be spaced apart from each other in the first direction DR1 with the light control part CCP1 interposed therebetween. An opening BW-OHa may be defined by two first barrier rib portions BW-V disposed adjacent to each other and two second barrier rib portions BW-H disposed adjacent to each other. The light control part CCP1 may be disposed in the opening BW-OHa. In the light control member OP-a according to an embodiment illustrated in FIGS. 10 to 12, the dam portion BW-Da may be disposed adjacent to the upper end portion (e.g., a side surface) or the lower end portion (e.g., another side surface) of the light control part CCP1 spaced apart from each other in the first direction DR1 in the light control part CCP1.

The division pattern layer BMP-a may include a lower pattern layer BMP-L and an upper pattern layer BMP-U stacked in the direction of the fourth direction axis DR4. The light control member OP-a according to an embodiment may include a division pattern layer BMP-a having a two-stage structure (or two-layered structure) in which two pattern layers are stacked. The lower pattern layer BMP-L may include a first barrier rib portion BW-V and a second barrier rib portion BW-H. The first barrier rib portion BW-V and the second barrier rib portion BW-H constituting the lower pattern layer BMP-L may be disposed on the color filter layer CFL. For example, the color filter layer CFL may be disposed on the base substrate BL.

The upper pattern layer BMP-U may include a dam portion BW-Da. The dam portion BW-Da of the upper pattern layer BMP-U may be disposed on the lower pattern layer BMP-L. Referring to FIG. 10, the dam portion BW-Da may be disposed between the light control parts CCP1 and CCP2 spaced apart from each other in the second direction DR2. On a plane defined by the first and second direction axes DR1 and DR2, the dam portion BW-Da may be formed as portions having a triangular shape. However, the shape of the dam portion BW-Da is not limited to what is illustrated in FIG. 10, etc., and the shape of the dam portion BW-Da may be changed within a range in which a portion having the maximum width in the dam opening BD-OHa to be described below is positioned between the light control parts CCP1 adjacent to each other in the first direction DR1.

The dam portions BW-Da may enable the dam opening BD-OHa to be defined between the light control parts CCP1 neighboring each other in the first direction DR1. The dam portions BW-Da may be provided in a form in which a surface defining the dam opening BD-OHa has an inclined surface, so that the dam opening BD-OHa has a maximum width W_{DM} between the light control parts CCP1 neighboring each other in the first direction DR1 and a separation distance between the dam portions BW-Da neighboring each other in the second direction DR2 is reduced as the dam portions BW-Da become farther away from a central portion of the dam opening BD-OHa. For example, the surface defining the dam opening BD-OHa is not limited to what is illustrated in FIG. 4 or 10, and the dam opening BD-OHa may be defined as including a straight surface parallel to the first direction axis DR1 or the second direction axis DR2, an oblique surface having an inclination with respect to the first direction axis DR1 or the second direction axis DR2, a curved surface at least partially curved, or the like.

In an embodiment, the upper pattern layer BMP-U may further include a connection dam portion BW-CN. The connection dam portion BW-CN may be disposed on the lower pattern layer BMP-L. The connection dam portion BW-CN may be disposed to overlap the second barrier rib portion BW-H. Referring to FIG. 10, the connection dam portion BW-CN may be formed in contact with a portion of the dam portion BW-Da. The dam portion BW-Da and the connection dam portion BW-CN may be integral with each other.

In the light control member OP-a according to an embodiment illustrated in FIGS. 10 to 12, the dam opening BD-OHa may be defined by the inclined surfaces of the dam portions BW-Da, and the dam portions BW-Da and the connection dam portions BW-CN may be connected to each other to be integral with each other.

Referring to FIGS. 10 to 12, the second distance (or second width) W_{DM} of the dam openings BD-OHa in the second direction DR2 may be greater than the first distance (or first width) W_{CP} of the openings BW-OH in the second direction DR2. In an embodiment, the second distance W_{DM} between the connection dam portions BW-CN spaced apart from each other in the second direction DR2 may be greater than the first distance W_{CP} between the first barrier rib portions BW-V spaced apart from each other in the second direction DR2.

The dam opening BD-OHa may be defined as a space between the dam portions BW-Da spaced apart from each other in the second direction DR2 with the light control part CCP1 interposed therebetween and side surfaces of the connection dam portions BW-CN connected to the dam portions BW-Da. The shape of the dam opening BD-OHa in a plan view may be a polygonal shape including side surfaces of the dam portions BW-Da defining the dam opening BD-OHa, the side surfaces of the connection dam portions BW-CN, and edge surfaces of the light control part CCP1 adjacent to the side surfaces of the dam portions BW-Da. In a plan view, the dam opening BD-OHa may have a polygonal shape including a portion having a maximum distance W_{DM}.

The remaining light control part CCP1-R may be disposed on the barrier layer CAP exposed from the dam opening BD-OHa. For example, the remaining light control part CCP1-R may be disposed in contact with a side surface of the connection dam portion BW-CN defining the dam opening BD-OHa. The remaining light control part CCP1-R may not be disposed on the upper surface of the connection dam portion BW-CN. The connection dam portion BW-CN may have liquid repellency, and accordingly, the remaining light control part CCP1-R may not spread to the upper surface of the connection dam portion BW-CN and may be disposed only in the dam opening BD-OHa.

In an embodiment, as the light control member OP-a includes the dam portion BW-Da, which is disposed on the lower pattern layer BMP-L defining the opening BW-OH and defines the dam opening BD-OHa adjacent to the opening BW-OH in which the light control part CCP1 is disposed, it is possible to exhibit/have excellent quality without any region in which the light control part CCP1 is not filled in the opening BW-OH.

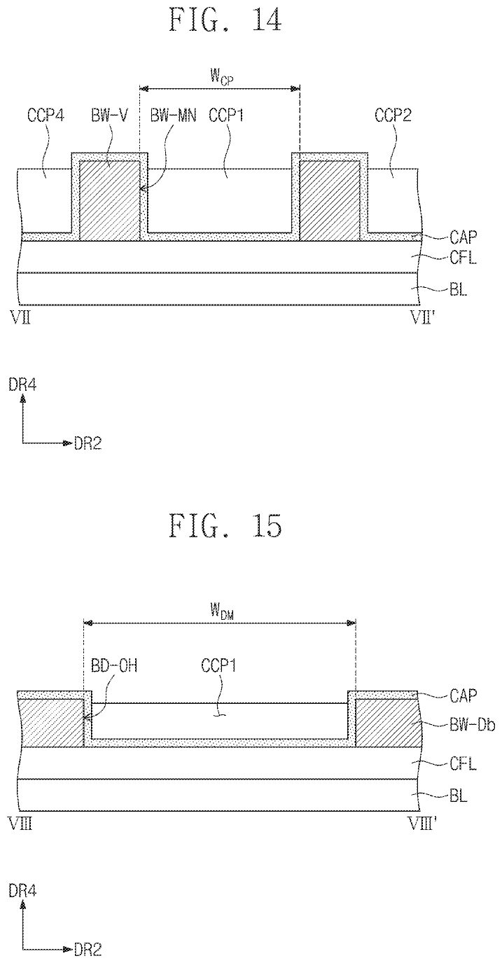

FIG. 13 is a schematic plan view of a light control member according to an embodiment. Each of FIGS. 14 and 15 is a schematic cross-sectional view of a portion of the light control member according to an embodiment. FIG. 14 is a schematic cross-sectional view of a portion taken along line VII-VII′ of FIG. 13, and FIG. 15 is a schematic cross-sectional view of a portion taken along line VIII-VIII′ of FIG. 13.

Referring to FIGS. 13 to 15, a light control member OP-b according to an embodiment may include light control parts CCP1, CCP2, CCP3, and CCP4 and a division pattern layer BMP-b including a first barrier rib portion BW-V, a second barrier rib portion BW-H, and a dam portion BW-Db. In the description of the light control member OP-b, the first light control part CCP1 will be representatively described as an example of the light control part CCP1.

The first barrier rib portions BW-V may extend in the first direction DR1 and be spaced apart from each other in the second direction DR2 with the light control part CCP1 interposed therebetween. The second barrier rib portions BW-H may extend in the second direction DR2 and be spaced apart from each other in the first direction DR1 with the light control part CCP1 interposed therebetween. In the light control member OP-b according to an embodiment, the dam portion BW-Db may be positioned adjacent to the central portion of the length of the light control part CCP1 in the first direction DR1.

In an embodiment, the first barrier rib portion BW-V, the second barrier rib portion BW-H, and the dam portion BW-Db may be formed on the same layer. For example, the division pattern layer BMP-b including the first barrier rib portion BW-V, the second barrier rib portion BW-H, and the dam portion BW-Db may have a one-stage structure (or one-layered structure).

In an embodiment, an opening BW-OHb may be defined by the first barrier rib portions BW-V, the second barrier rib portions BW-H, and the dam portions BW-Db. In the light control member OP-b according to an embodiment, the opening BW-OHb may include a main opening BW-MN and a dam opening BD-OH. The main opening BW-MN and the dam opening BD-OH may be integral with each other. The main opening BW-MN may be defined as a space between the first barrier rib portions BW-V spaced apart from each other in the second direction DR2 with the light control part CCP1 interposed therebetween, and the dam opening BD-OH may be defined as a space between the dam portions BW-Db and the second barrier rib portions BW-H spaced apart from each other in the second direction DR2 with the light control part CCP1 interposed therebetween.

The width of the dam opening BD-OH in the second direction DR2 may be greater than the width of the main opening BW-MN in the second direction DR2. The shape of the opening BW-OHb in a plan view may be a polygonal shape including a portion having a maximum width in the second direction DR2 between the dam portions BW-Db spaced apart from each other in the second direction DR2 with the light control part CCP1 interposed therebetween.

Compared to the light control members OP and OP-a according to the embodiments described with reference to FIGS. 4 to 12, etc., the light control part CCP1 may also be disposed in the dam opening BD-OH in the light control member OP-b according to an embodiment including the division pattern layer BMP-b having a one-stage structure (or one-layered structure). The thickness of the light control part CCP1 disposed in the dam opening BD-OH may be similar to the thickness of the light control part CCP1 disposed in the main opening BW-MN. However, embodiments are not limited thereto, and the thickness of the light control part CCP1 disposed in the dam opening BD-OH may not be uniform, and the light control part CCP1 may not be sufficiently filled in a portion of the dam opening BD-OH.

For example, in an embodiment, since the light control member OP-b includes the division pattern layer BMP-b having a single-stage structure (or single-layered structure) and the division pattern layer BMP-b includes the dam portions BW-Db defining the opening BW-OH, a portion of which has a width greater than those of the remaining portions, the light control part CCP1 disposed in the main opening BW-MN may have excellent appearance characteristics. In an embodiment, in case that the light control part CCP1 is formed, by providing the opening BW-OHb including the dam opening BD-OH with an excessive amount of ink composition equal to or greater than the weight of the ink composition which fills the main opening BW-MN, the ink composition may sufficiently wet the inside of the main opening BW-MN and the entire region of the main opening BW-MN may be filled, so that the light control part CCP1 finally formed in the main opening BW-MN may exhibit/have excellent appearance quality.

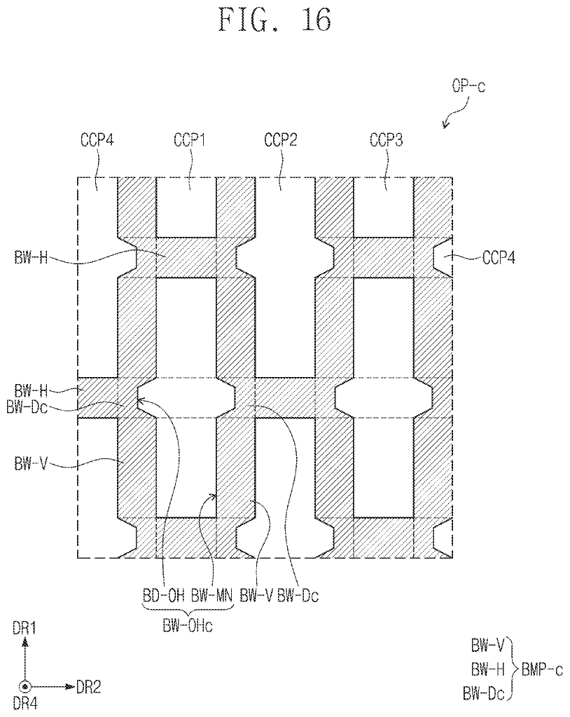

FIG. 16 is a schematic plan view of a light control member according to an embodiment. A light control member OP-c according to an embodiment illustrated in FIG. 16 may include the division pattern layer BMP-c having a one-stage structure (or one-layered structure). The light control member OP-c according to an embodiment may include light control parts CCP1. CCP2, CCP3, and CCP4 and a division pattern layer BMP-c that divides the light control parts CCP1, CCP2, CCP3, and CCP4.

The division pattern layer BMP-c may include a first barrier rib portion BW-V, a second barrier rib portion BW-H, and a dam portion BW-Dc. The first barrier rib portion BW-V, the second barrier rib portion BW-H, and the dam portion BW-Dc may be formed to be connected to each other. The first barrier rib portion BW-V, the second barrier rib portion BW-H, and the dam portion BW-Dc may be integral with each other.

The first barrier rib portions BW-V may be disposed to be spaced apart from each other in the second direction DR2 with the light control part CCP1 interposed therebetween, and the second barrier rib portions BW-H may be disposed to be spaced apart from each other in the first direction DR1 with the light control part CCP1 interposed therebetween. The dam portions BW-Dc may be connected to the first barrier rib portion BW-V in the first direction DR1. For example, the dam portions BW-Dc may be connected to the second barrier rib portion BW-H in the second direction DR2. A separation distance between the dam portions BW-Dc spaced apart from each other in the second direction DR2 with the light control part CCP1 interposed therebetween may be greater than a separation distance between the first barrier rib portions BW-V spaced apart from each other in the second direction DR2 with the light control part CCP1 interposed therebetween.

The division pattern layer BMP-c may define an opening BW-OHc in which the distance (or gap) of the central portion is greater than the distances (or gaps) of the remaining portions. The opening BW-OHc may include a dam opening BD-OH positioned in a central portion and a main opening positioned on both sides of the dam opening BD-OH in the first direction DR1 with the dam opening BD-OH interposed therebetween. In the light control member OP-c according to an embodiment, the light control part CCP1 may be disposed in the main opening BW-MN and the dam opening BD-OH. The thickness of the light control part CCP1 disposed in the dam opening BD-OH may be similar to the thickness of the light control part CCP1 disposed in the main opening BW-MN. However, embodiments are not limited thereto, and the thickness of the light control part CCP1 disposed in the dam opening BD-OH may not be uniform, and the light control part CCP1 may not be sufficiently filled in a portion of the dam opening BD-OH.

In an embodiment, as the light control member OP-c include the division pattern layer BMP-c having a one-stage structure (or one-layered structure) and the division pattern layer BMP-c includes the dam portions BW-Dc defining the opening BW-OHc, a portion of which has a width greater than those of the remaining portions, the light control part CCP1 disposed in the main opening BW-MN may exhibit/have excellent appearance quality.

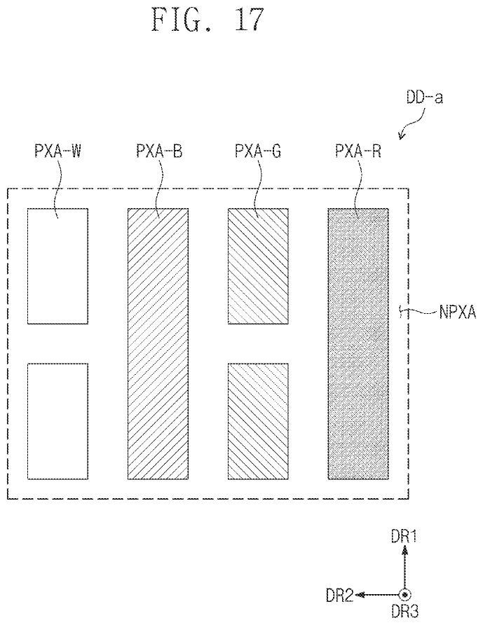

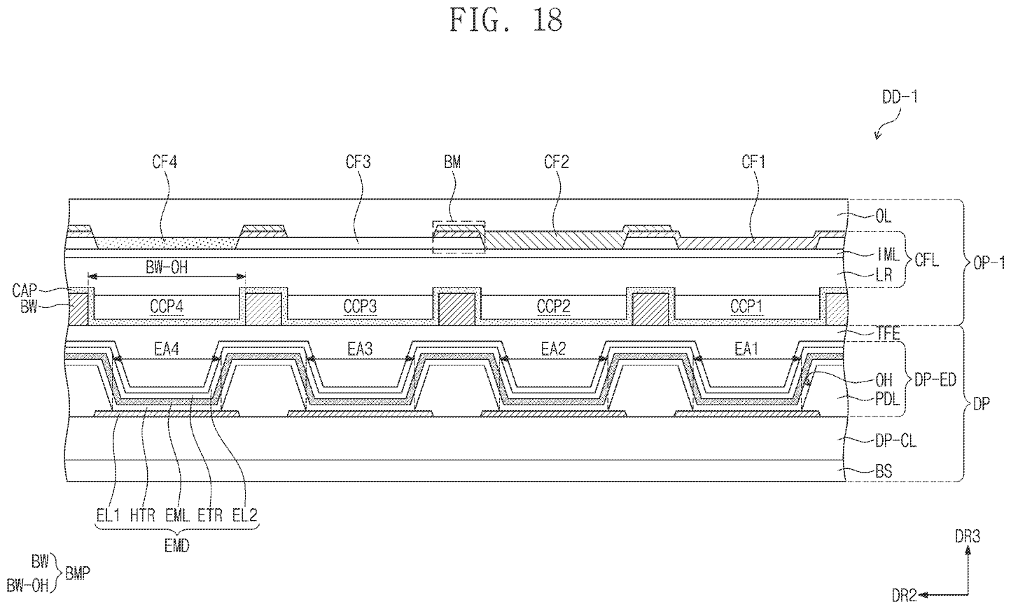

FIG. 17 is a schematic plan view of a display device according to an embodiment. FIG. 17 is a schematic plan view illustrating a partial region of the display device as in FIG. 2. Referring to FIG. 17, in the display device DD-a according to an embodiment, the size of some pixel regions PXA-R and PXA-B divided by the peripheral region NPXA in a plan view may be larger than the size of the other pixel regions PXA-G and PXA-W in a plan view In the case of the display device DD-a according to an embodiment illustrated in FIG. 17, the light control members OP-b and OP-c according to an embodiment described with reference to FIGS. 13 to 16, etc. may be included. For example, in an embodiment, boundaries between the peripheral region NPXA and the pixel regions PXA-R, PXA-G, PXA-B, and PXA-W may be determined by the light blocking pattern layer BM (see FIG. 3). FIG. 3 illustrates that the light blocking pattern layer BM is provided in a form in which filter portions CF1, CF2, and CF3 are stacked, but embodiments are not limited thereto, and the light blocking pattern layer BM may be disposed in the color filter layer CFL (see FIG. 3) as a separate light blocking layer, or may be disposed on the base substrate BL (see FIG. 3).

For example, in case that the light control members OP-b and OP-c according to an embodiment described with reference to FIGS. 13 to 16 are included, the display device having the size and arrangement form of the pixel regions PXA-R. PXA-G, PXA-B, and PXA-W illustrated in FIG. 2 may be implemented. The arrangement form and size of the pixel regions PXA-R. PXA-G, PXA-B, and PXA-W may be determined by the light blocking pattern layer BM (see FIG. 3) defining the peripheral region NPXA, and in the case of having the structure of the light control parts CCP1, CCP2, CCP3, and CCP4 in the light control members OP-b and OP-c illustrated in FIGS. 13 to 16, it is possible to have the arrangement form of the pixel regions PXA-R. PXA-G, PXA-B, and PXA-W of the display device DD according to the embodiment illustrated in FIG. 2.

FIG. 18 is a schematic cross-sectional view of a display device according to an embodiment. A display device DD-1 according to an embodiment illustrated in FIG. 18 differs from the display device DD according to the embodiment illustrated in FIG. 3 in that the base substrate BL (see FIG. 3) is omitted.

Referring to FIG. 18, the display device DD-1 according to an embodiment may include a display panel DP including a display element layer DP-ED and a light control member OP-1 disposed on the display panel DP. In the display device DD-1 according to an embodiment, the light control member OP-1 may be disposed (e.g., directly disposed) on the display panel DP. A light control layer CCL and a color filter layer CFL may be sequentially stacked above the display panel DP in the direction of the third direction axis DR3. For example, the light control member OP-1 may further include an organic layer OL disposed on the color filter layer CFL. The organic layer OL may cover the step differences of the filter portions CF1, CF2, CF3, and CF4 of the color filter layer CFL and provide a flat surface. The organic layer OL may be the uppermost surface of the light control member OP-1.

As described with reference to FIG. 3, etc., the color filter layer CFL may include the filter portions CF1, CF2, CF3, and CF4 that transmit light of different wavelength ranges. In an embodiment, the fourth filter portion CF4 of the color filter layer CFL may be omitted.

The color filter layer CFL may include a low refractive index layer LR. The low refractive index layer LR may be disposed on the light control layer CCL to block the light control parts CCP1, CCP2, CCP3, and CCP4 from being exposed to moisture/oxygen. For example, the color filter layer CFL may further include an insulating layer IML. The insulating layer IML may be an inorganic layer that seals lower structures. The insulating layer IML may be omitted.

The light control layer CCL may include a division pattern layer BMP to divide the light control parts CCP1, CCP2, CCP3, and CCP4. The division pattern layer BMP may include a barrier rib portion BW and an opening BW-OH. In the light control layer CCL illustrated in FIG. 18, the barrier rib portion BW may correspond to the first barrier rib portion BW-V (see FIG. 4, etc.) in the embodiment of the light control member described with reference to FIGS. 4 to 16, etc.

The light control member according to the embodiment described with reference to FIGS. 4 to 16, etc. may be used as the light control member OP-1 in the display device DD-1 according to the embodiment illustrated in FIG. 18. For example, by including the division pattern layer BMP including the dam opening having a width in the second direction DR2 greater than a width of the opening in the second direction DR2 in a portion in which the light control parts CCP1, CCP2, CCP3, and CCP4 are disposed to correspond to the pixel regions PXA-R. PXA-G, PXA-B, and PXA-W, the light control parts CCP1, CCP2, CCP3, and CCP4 in the portion corresponding to the pixel regions PXA-R. PXA-G, PXA-B, and PXA-W may exhibit/have excellent appearance quality, and accordingly, the display quality of the display device may be improved.

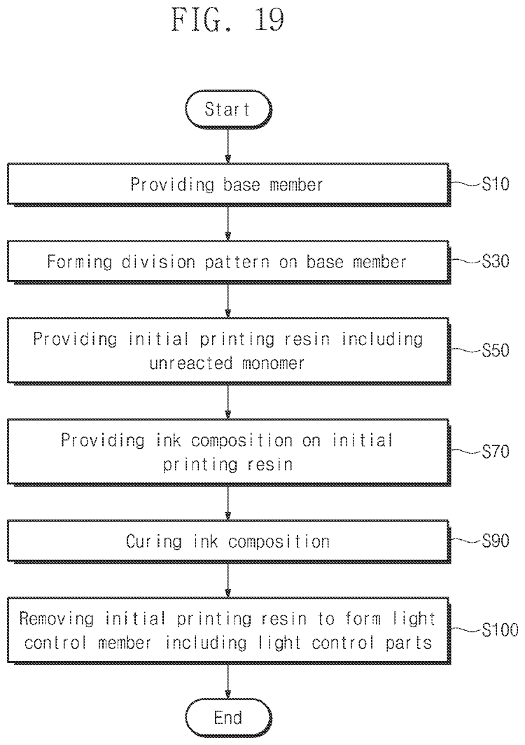

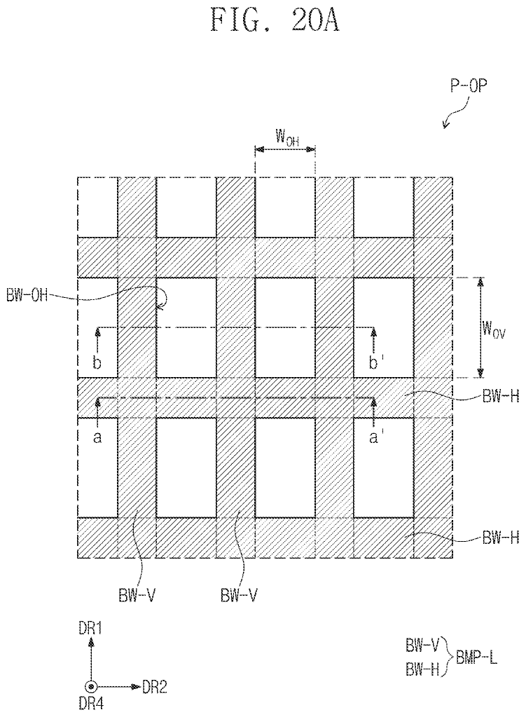

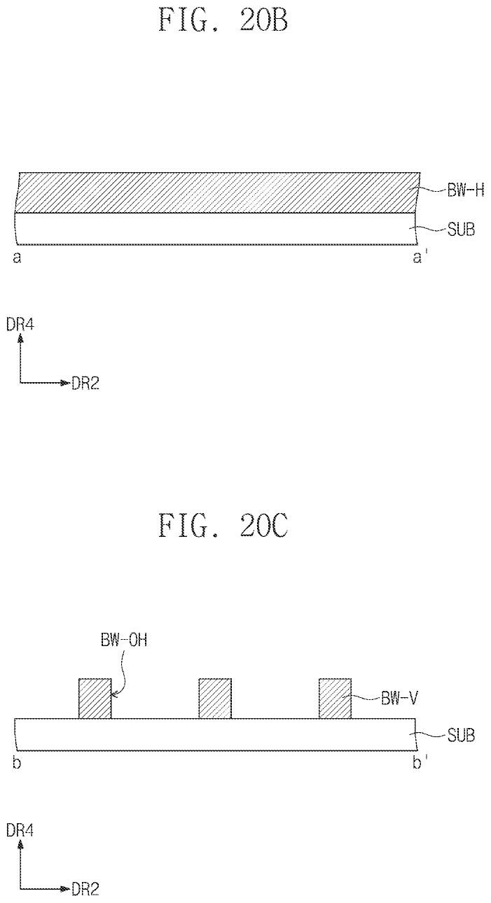

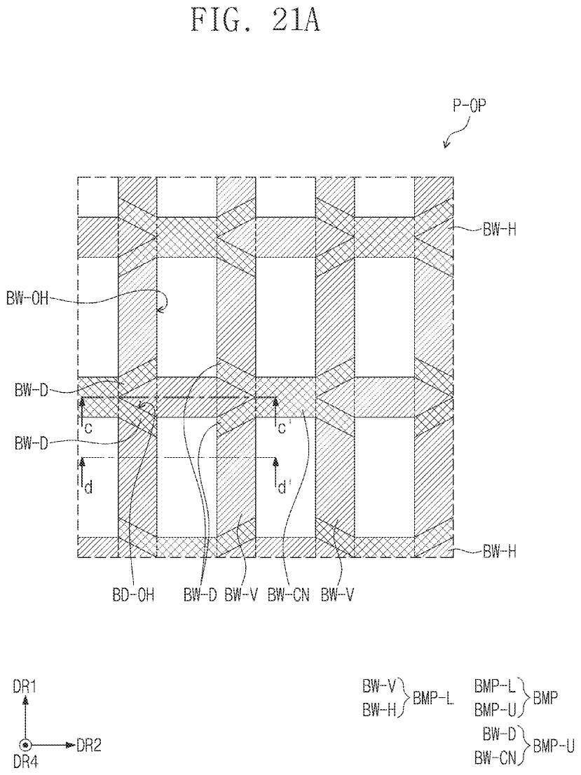

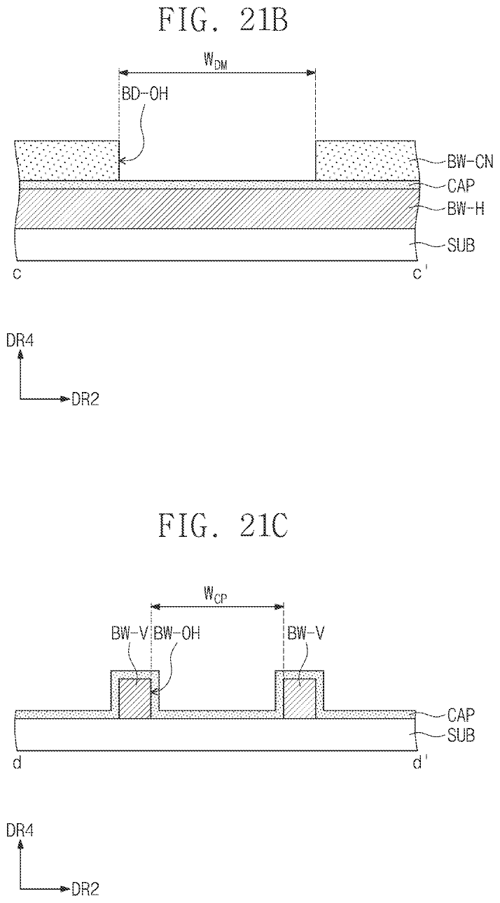

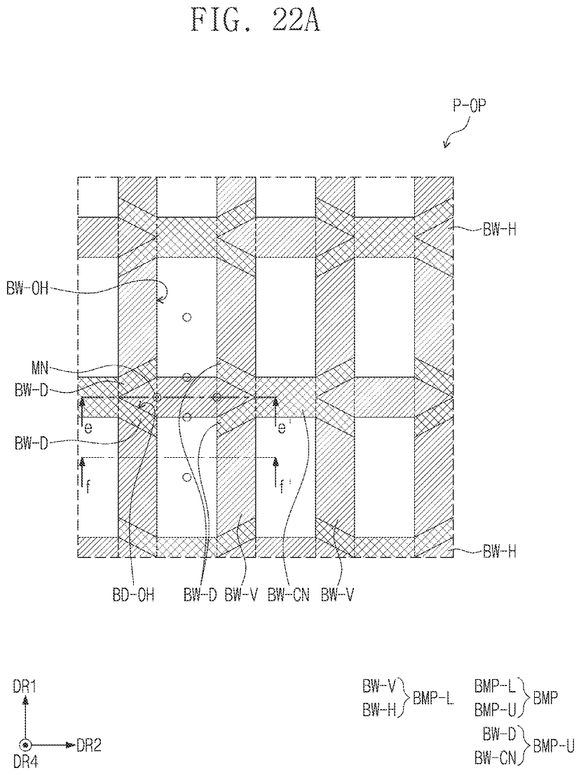

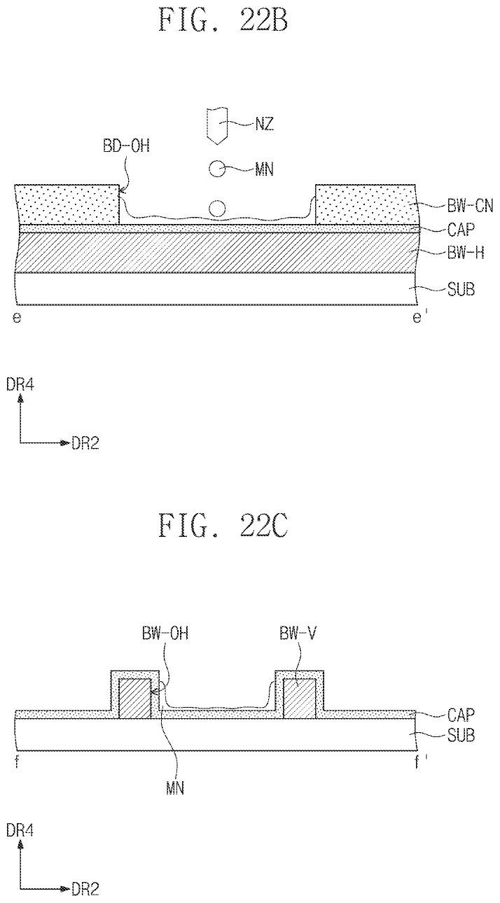

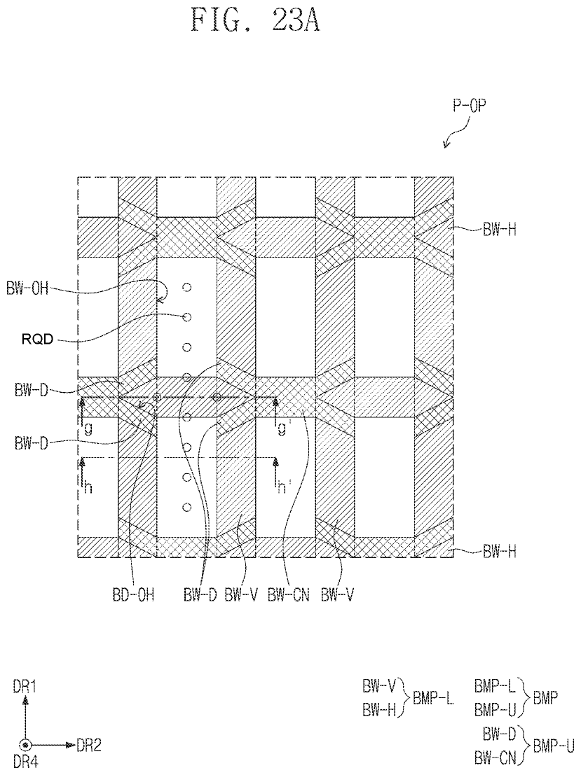

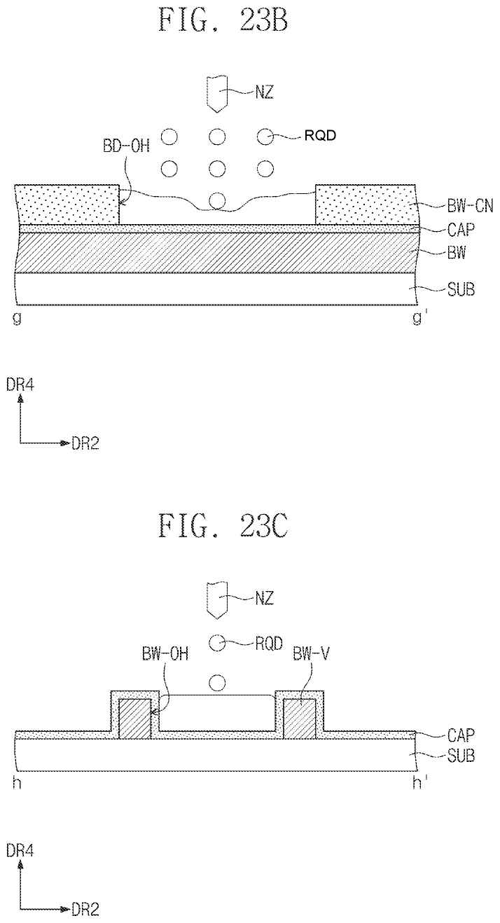

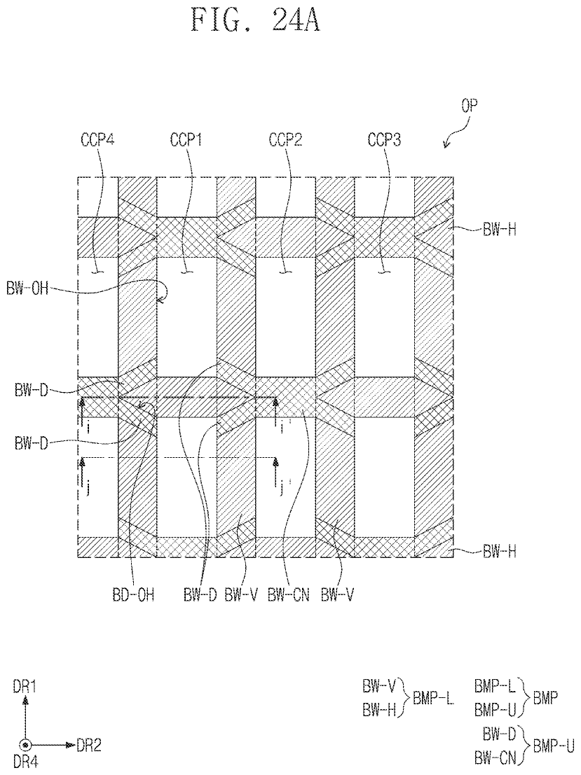

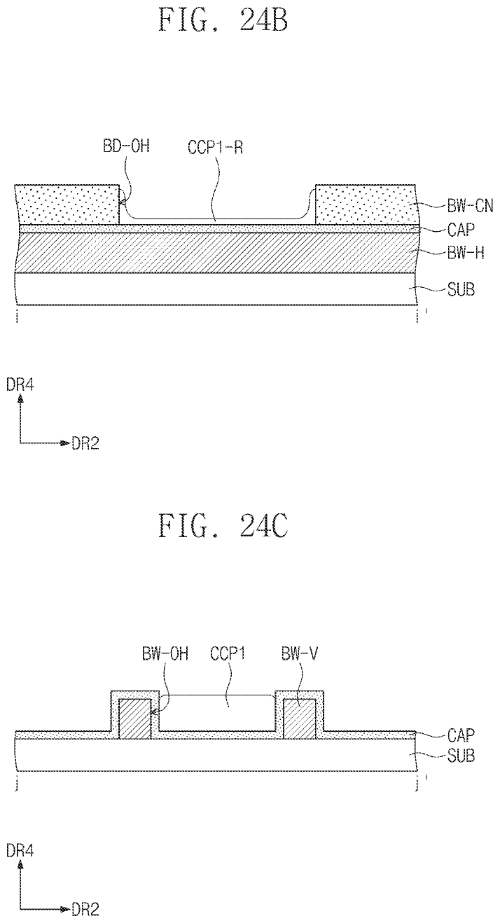

Hereinafter, a method of manufacturing a display device according to an embodiment will be described with reference to FIGS. 19 to 24C. FIG. 19 is a flowchart of a method of manufacturing a display device according to an embodiment. Each of FIGS. 20A to 24C schematically illustrates a step of the method of manufacturing the display device according to an embodiment.

Referring to FIG. 19, the method of manufacturing the display device according to an embodiment may include providing a base member (S10), forming a division pattern layer on the base member (S30), providing an initial printing resin including unreacted monomer (S50), providing an ink composition on the initial printing resin (S70), curing the ink composition (S90), and removing the initial printing resin to form a light control member including light control parts (S100).

In the method of manufacturing the display device according to an embodiment, the providing of the base member (S10) may include providing a base layer on which a division pattern layer is formed. In case that the display device DD according to an embodiment illustrated in FIG. 3 is manufactured, a base member SUB (see FIG. 20B) may include a base substrate BL (see FIG. 3) and a color filter layer CFL (see FIG. 3) disposed on the base substrate BL (see FIG. 3). For example, in case that the display device DD-1 according to an embodiment illustrated in FIG. 18 is manufactured, the base member SUB (see FIG. 20B) may be a display panel DP including the display element layer DP-ED (see FIG. 18).

Hereinafter, FIGS. 20A to 24C illustrate and describe some steps of the method of manufacturing the display device DD according to an embodiment illustrated in FIG. 3, and the contents of the method of manufacturing the display device according to an embodiment described below may be equally applied to the method of manufacturing the display device DD according to an embodiment illustrated in FIG. 18 except for differences such as the type of the base member and the stacking direction of the light control member.

Hereinafter, FIGS. 20A to 24C illustrate steps of the method of manufacturing the display device, which includes the forming of the light control member including the division pattern layer having a two-stage structure (or two-layered structure). However, the method of manufacturing the display device according to an embodiment described with reference to FIGS. 19 to 24C may be applied to the method of manufacturing the display device including the light control member including the division pattern layer having a one-stage structure (or one-layered structure) in addition to a case in which the division pattern layer having a two-stage structure (or two-layered structure) is included.

FIGS. 20A to 20C and FIGS. 21A to 21C partially illustrate the forming of the division pattern layer on the base member (S30) as an example. FIG. 20A is a schematic plan view illustrating a portion of a preliminary light control member, and each of FIGS. 20B and 20C is a schematic cross-sectional view illustrating a portion of the preliminary light control member. FIG. 21A is a schematic plan view illustrating a portion of the preliminary light control member, and each of FIGS. 21B and 21C is a schematic cross-sectional view illustrating a portion of the preliminary light control member.

FIG. 20B is a schematic cross-sectional view of a portion taken along line a-a′ of FIG. 20A, and FIG. 20C is a schematic cross-sectional view of a portion taken along line b-b′ of FIG. 20A. FIG. 21B is a schematic cross-sectional view of a portion taken along line c-c′ of FIG. 21A, and FIG. 21C is a schematic cross-sectional view of a portion taken along line d-d′ of FIG. 21A.

In FIGS. 20A to 21C, a preliminary light control member P-OP may be in a state before the light control part CCP1 (see FIG. 24C) is disposed. In FIG. 20A, the preliminary light control member P-OP may be in a state in which the division pattern layer BMP (see FIG. 21A) including the first barrier rib portion BW-V and the second barrier rib portion BW-H is formed on the base member SUB. FIG. 20A illustrates a state in which the lower pattern layer BMP-L included in the division pattern layer BMP (see FIG. 21A) is formed on the base member SUB. An opening BW-OH may be defined in the preliminary light control member P-OP. The opening BW-OH may be defined by the first barrier rib portions BW-V and the second barrier rib portions BW-H. On a plane defined by the first and second direction axes DR1 and DR2, a width W_{OV} of the opening BW-OH in the direction of the first direction axis DR1 may be greater than a width W_{OH} of the opening BW-OH in the direction of the second direction axis DR2. For example, in a plan view, the openings BW-OH may have a rectangular shape in which a length in the first direction DR1 is greater than a length in the second direction DR2. However, embodiments are not limited thereto, and the openings BW-OH in which the light control part will be disposed later may have various shapes according to an arrangement of the first barrier rib portion BW-V and the second barrier rib portion BW-H.

Referring to FIGS. 21A to 21C, the division pattern layer BMP may include a first barrier rib portion BW-V, a second barrier rib portion BW-H, and a dam portion BW-D. The first barrier rib portion BW-V and the second barrier rib portion BW-H may form a lower pattern layer BMP-L, and the dam portion BW-D may form an upper pattern layer BMP-U disposed on the lower pattern layer BMP-L.

The forming of the division pattern layer on the base member (S30) may include forming a barrier layer CAP. The barrier layer CAP may be provided to cover the lower pattern layer BMP-L and a surface of the base member SUB exposed through the opening BW-OH after the lower pattern layer BMP-L is formed. After forming the barrier layer CAP, the upper pattern layer BMP-U may be formed.

Referring to FIGS. 21A to 21C, a dam portion BW-D may be disposed on the barrier layer CAP. The dam portion BW-D may be disposed on the lower pattern layer BMP-L with defining the dam opening BD-OH. A width W_{DM} in the second direction DR2 of the dam opening BD-OH defined between the dam portions BW-D may be greater than a width W_{CP} in the second direction DR2 of the opening BW-OH defined between the first barrier rib portions BW-V.

The upper pattern layer BMP-U formed on the lower pattern layer BMP-L may include a dam portion BW-D and a connection dam portion BW-CN extending from the dam portion BW-D. The upper pattern layer BMP-U may have a liquid repellent property. Due to the upper pattern layer BMP-U having liquid repellency, an ink composition to be subsequently provided may not be disposed on the upper surface of the upper pattern layer BMP-U.

Hereinafter, FIGS. 22A to 24C illustrate a step of the method of manufacturing the display device including the forming of the first light control part CCP1 (see FIG. 3). However, the method of forming the light control member in the display device manufacturing method to be described with reference to FIGS. 22A to 24C may be equally applied to the manufacture of the second to fourth light control parts CCP2, CCP3, and CCP4 in addition to the first light control part CCP1.

FIGS. 22A to 22C may illustrate the providing of an initial printing resin including unreacted monomer (S50). FIG. 22A is a schematic plan view illustrating a portion of the preliminary light control member, and each of FIGS. 22B and 22C is a schematic cross-sectional view of a portion of the preliminary light control member. FIG. 22B is a schematic cross-sectional view of a portion taken along line e-e′ of FIG. 22A, and FIG. 22C is a schematic cross-sectional view of a portion taken along line f-f of FIG. 22A. The initial printing resin MN may increase the wetting property of a subsequently provided ink composition RQD (see FIG. 23A) in the opening BW-OH.

The initial printing resin MN may be first provided into the opening BW-OH and the dam opening BD-OH prior to providing the ink composition RQD (see FIG. 23A) through a nozzle NZ of an inkjet printing machine. The unreacted monomer included in the initial printing resin MN may include a portion formed by removing a polymerization reacting group from a base monomer included in the ink composition RQD (see FIG. 23A). For example, the unreacted monomer may be an unreacted monomer from which a polymerization reacting group such as an acrylate group may be removed. For example, the unreacted monomer may further include an end group in a portion, from which the polymerization reacting group is removed, for improving compatibility with the ink composition RQD (see FIG. 23A). The unreacted monomer may selectively include a hydrophilic group or a hydrophobic group as an end group. A hydroxy group (—OH), a carboxy group (—COOH), and the like may be used as the hydrophilic group, and an alkyl group and the like may be used as the hydrophobic group.

For example, in case that the base monomer included in the ink composition RQD (see FIG. 23A) is hexadimethylene diacrylate represented by Formula 1 below, the unreacted monomer may be represented by Formula 2 including a portion formed by removing acrylate groups on both sides from Formula 1.

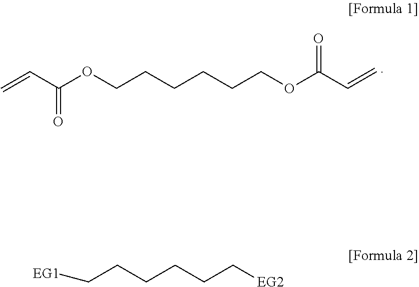

In Formula 2, EG1 and EG2 are end groups and may be hydrophilic or hydrophobic groups other than acrylate groups.

The vapor pressure of the unreacted monomer may be about 10⁻⁶ mmHg to about 10⁻¹ mmHg. The vapor pressure may be a vapor pressure at room temperature. By sharing a structure, which excludes the polymerization reacting group, with the base monomer used in the ink composition RQD (see FIG. 23A), the unreacted monomer may exhibit/have excellent compatibility with the ink composition RQD (see FIG. 23A), and by having a vapor pressure of about 10⁻⁶ mmHg to about 10⁻¹ mmHg, the unreacted monomer may be easily removed in case that the light control part is formed.

The unreacted monomer may have a surface energy of about 1 dyne/cm to about 40 dyne/cm and a viscosity of about 1 cp to about 40 cp. Due to these physical characteristics of the unreacted monomer, the inside of the opening BW-OH and the dam opening BD-OH may be sufficiently wetted with the unreacted monomer.

The initial printing resin may further include an organic solvent in addition to the unreacted monomer. For example, the vapor pressure of the organic solvent included in the initial printing resin may be about 1 mmHg or less. The unreacted monomer and the organic solvent included in the initial printing resin may be used to increase the wetting property of an ink composition to be provided later. In the state of a final product, the unreacted monomer and the organic solvent may be removed without remaining.

As an organic solvent, at least one of propyleneglycol monomethylether acetate (PGMEA), dimethylacetamide (DMA), cyclohexylamime (CHA), dipropylene glycol methylether acetate (DPMA), or hexane may be used. The organic solvent may have excellent compatibility with the unreacted monomer and the ink composition.

FIGS. 23A to 23C illustrate the providing of the ink composition on the initial printing resin (S70). FIG. 23A is a schematic plan view illustrating a portion of the preliminary light control member, and each of FIGS. 23B and 23C is a schematic cross-sectional view of a portion of the preliminary light control member. FIG. 23B is a schematic cross-sectional view of a portion taken along line g-g′ of FIG. 23A, and FIG. 23C is a schematic cross-sectional view of a portion taken along line h-h′ of FIG. 23A.

In the providing of the initial printing resin including the unreacted monomer (S50) described with reference to FIGS. 22A to 22C, the ink composition RQD may be provided above the initial printing resin.

The ink composition RQD may include a base monomer, a quantum dot, and a scatterer. For example, in manufacturing the third light control part CCP3 (see FIG. 3), the ink composition may include a base monomer and a scatterer, but may not include a quantum dot.

In the ink composition RQD, hexamethylene diacrylate, tetraethylene glycol diacrylate, dipropylene glycol diacrylate, tripropylene glycol diacrylate, and the like may be used as a base monomer. However, embodiments are not limited thereto, and monomers may be used without limitation as long as they do not affect the light-emitting characteristics of the quantum dot and are capable of polymerization.

The ink composition RQD may be provided above the initial printing resin provided through the nozzle NZ of the inkjet printing machine. The ink composition RQD may be provided to the opening BW-OH defined between the first barrier rib portions BW-V and the dam opening BD-OH defined between the light control parts CCP1 spaced apart from each other in the first direction DR1.

The ink composition RQD provided to the dam opening BD-OH may be transferred to neighboring openings BW-OH. Accordingly, the ink composition RQD may be uniformly provided in a sufficient amount to all of the openings BW-OH without any unfilled region in the openings BW-OH.

By providing the ink composition RQD in a sufficient amount through the dam opening BD-OH in the method of manufacturing the display device according to an embodiment, it is possible to improve a process margin for excluding a case in which the ink composition is misplaced and mixed into a neighboring light control part in the second direction DR2 in case that a separation distance between neighboring light control parts in the second direction DR2 is reduced for high resolution characteristics.

FIGS. 24A to 24C illustrate the forming of the light control member (S100). FIG. 24A is a schematic plan view illustrating a light control member manufactured by the method of manufacturing the display device according to an embodiment. FIG. 24B is a schematic cross-sectional view of a portion taken along line i-i′ of FIG. 24A, and FIG. 24C is a schematic cross-sectional view of a portion taken along line j-j′ of FIG. 24A.

FIGS. 24A to 24C illustrate a portion of the light control member OP after performing the curing of the ink composition (S90) and the removing of the initial printing resin to form the light control member including the light control parts (S100).

In the curing of the ink composition (S90), the light control part CCP1 in a cured state may be formed by inducing the polymerization of the ink composition RQD (see FIG. 23A) with the use of heat or light. For example, the base monomer of the ink composition may be polymerized by ultraviolet rays or the like to form a base resin constituting the light control part CCP1. The light control part CCP1 may include a base resin formed from the polymerization of the base monomer, a quantum dot dispersed in the base resin, and a scatterer dispersed in the base resin. For example, the third light control part CCP3 may include a base resin formed from the polymerization of the base monomer and a scatterer dispersed in the base resin.

In the forming of the light control part (S100), the removing of the initial printing resin may be performed by providing heat to volatilize and remove a remaining initial printing resin after the curing of the ink composition.

After removing the initial printing resin, the light control part CCP1 may be disposed in the opening BW-OH defined between the first barrier rib portions BW-V, and a remaining light control part CCP1-R may remain in the dam opening BD-OH defined between the dam portions BW-D. The amount of the remaining light control part CCP1-R may vary according to the amount of the provided ink composition, the degree of progress of polymerization, and the like.

After forming the light control member OP illustrated in FIG. 24A, etc., the display device may be manufactured by further performing the providing of the display panel including the display element layer and the assembling of the light control member and the display panel.

For example, in the case of manufacturing the display device DD-1 illustrated in FIG. 18, etc., the assembling of the light control member and the display panel may not be performed separately, and the light control member may be formed (e.g., directly formed) on the base member SUB which is the display panel.

By including steps of manufacturing the display device such as the forming of a division pattern layer including a dam portion defining a dam opening having a width larger than that of an opening in which a light control part is disposed, the first-jetting of an initial printing resin in the opening and the dam opening defined in the division pattern layer, and then the providing of the ink composition on the initial printing resin, the method of manufacturing the display device according to an embodiment may be used for manufacturing the display device including the light control part having excellent print quality. Since the display device manufactured by the method of manufacturing the display device according to an embodiment causes no color mixing of the ink composition between the light control parts and has no region in which the ink composition is not filled in case that the light control parts are arranged to correspond to the arrangement of high-resolution pixel regions, it is possible to exhibit/have excellent display quality.

As the display device according to an embodiment includes a light control member having a division pattern layer including a dam opening having a width in a direction greater than that of a light control part in the direction, it is possible to exhibit/have improved display quality due to the excellent appearance quality of the light control parts.

In the display device according to an embodiment, a distance between the barrier rib portions disposed with the light control part interposed therebetween in a region may be provided to be greater than the distance between the barrier rib portions in other regions, so that the light control part may have uniform appearance quality over the entire pixel region and the display device may exhibit/have excellent display quality.

In the method of manufacturing the display device according to an embodiment, a distance between the barrier rib portions disposed with the light control part interposed therebetween in a region may be provided to be greater than the distance between the barrier rib portions in other regions, and an unreacted monomer may be first provided. The method may be used for manufacturing a display device having excellent display quality.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a display panel that provides source light; and
a light control member disposed on the display panel, the light control member comprising:
a plurality of light control parts, and
a division pattern layer that divides the plurality of light control parts, wherein the division pattern layer comprises:
a plurality of first barrier rib portions extending in a first direction and spaced apart from each other by a first distance in a second direction perpendicular to the first direction, wherein the plurality of light control parts are disposed between the plurality of first barrier rib portions;
a plurality of second barrier rib portions extending in the second direction and spaced apart from each other in the first direction, wherein the plurality of light control parts are disposed between the plurality of second barrier rib portions; and
a plurality of dam portions spaced apart from each other in the second direction by a second distance greater than the first distance.

2. The display device of claim 1, wherein the plurality of light control parts comprise:
a plurality of first light control parts that emit light of a first wavelength range and arranged in the first direction; and
a plurality of second light control parts that emit light of a second wavelength range, respectively spaced apart from the plurality of first light control parts in the second direction, and arranged in the first direction.

3. The display device of claim 1, wherein each of the plurality of dam portions is disposed at an upper end portion or a lower end portion of each of the plurality of light control parts spaced apart from each other in the first direction, or disposed at a central portion of a length of each of the plurality of light control parts in the first direction.

4. The display device of claim 1, wherein the division pattern layer comprises:
a lower pattern layer comprising the plurality of first barrier rib portions and the plurality of second barrier rib portions; and
an upper pattern layer disposed on the lower pattern layer and comprising the plurality of dam portions.

5. The display device of claim 4, wherein the plurality of dam portions have liquid repellency.

6. The display device of claim 4, wherein:
a plurality of openings are defined by the plurality of first barrier rib portions and the plurality of second barrier rib portions; and
a dam opening is defined between neighboring dam portions in the second direction.

7. The display device of claim 6, wherein the dam opening is defined on the plurality of second barrier rib portions.

8. The display device of claim 6, wherein
each of the plurality of light control parts is disposed in each of the plurality of openings, and
a remaining light control part, which is formed of a same material as that of the plurality of light control parts adjacent to the remaining light control part in the first direction, is disposed in the dam opening.

9. The display device of claim 6, wherein a shape of the dam opening in a plan view defined by the plurality of dam portions spaced apart from each other in the second direction and edge portions of the plurality of light control parts neighboring each other in the first direction is a polygon comprising a portion in which a distance between the neighboring dam portions is maximized in the second direction.

10. The display device of claim 7, wherein the upper pattern layer is disposed on the lower pattern layer and further comprises connection dam portions extending from the plurality of dam portions in the second direction.

11. The display device of claim 10, wherein
the plurality of light control parts comprise:
n first light control parts that emit light of a first wavelength range and arranged in the first direction; and
n second light control parts respectively spaced apart from the n first light control parts in the second direction, and arranged in the first direction, the n second light control parts that emit light of a second wavelength range,
a first dam opening is defined between an (m+1)-th first light control part and an (m+2)-th first light control part,
a second dam opening is defined between an m-th second light control part and an (m+1)-th second light control part,
n is an integer greater than or equal to 1, and
m is an odd or even number.

12. The display device of claim 11, wherein:
a first connection dam portion extending from first dam portions defining the first dam opening is disposed between an (m+1)-th second light control part and an (m+2)-th second light control part; and
a second connection dam portion extending from second dam portions defining the second dam opening is disposed between an m-th first light control part and an (m+1)-th first light control part.

13. The display device of claim 10, wherein:
the dam opening is defined as a space between the plurality of dam portions disposed to be spaced apart from each other and side surfaces of the connection dam portions adjacent to the plurality of dam portions; and
a shape of the dam opening in a plan view has a polygonal shape including side surfaces of the plurality of dam portions defining the dam opening, the side surfaces of the connection dam portions, and edge surfaces of the plurality of light control parts adjacent to the side surfaces of the plurality of dam portions.

14. The display device of claim 1, wherein the plurality of first barrier rib portions, the plurality of second barrier rib portions, and the plurality of dam portions are formed on a same layer.

15. The display device of claim 14, wherein:
an opening is defined by the plurality of first barrier rib portions, the plurality of second barrier rib portions, and the plurality of dam portions, and
the plurality of light control parts are disposed in the opening.

16. The display device of claim 15, wherein the plurality of dam portions are disposed adjacent to a central portion of a length of each of the plurality of light control parts in the first direction.

17. The display device of claim 16, wherein the opening comprises:
a main opening defined between the plurality of first barrier rib portions spaced apart from each other in the second direction, wherein the plurality of light control parts are disposed between the plurality of first barrier rib portions; and
a dam opening defined between the plurality of second barrier rib portions and the plurality of dam portions spaced apart from each other in the second direction, wherein the plurality of light control parts are disposed between the plurality of first barrier rib portions.

18. The display device of claim 17, wherein a shape of the opening in a plan view is a polygon comprising a portion in which a width of the dam opening in the second direction is greater than a width of the main opening in the second direction.

19. The display device of claim 1, wherein:
the light control member further comprises:
a base substrate, and
a color filter layer comprising a plurality of filter portions that transmit light of different wavelengths,
the plurality of light control parts are disposed between the display panel and the color filter layer, and
the color filter layer is disposed between the plurality of light control parts and the base substrate.

20. The display device of claim 19, wherein:
the division pattern layer comprises:
a lower pattern layer comprising the plurality of first barrier rib portions and the plurality of second barrier rib portions; and
an upper pattern layer disposed on the lower pattern layer and comprising the plurality of dam portions, and
a thickness of the upper pattern layer corresponds to a distance between the display panel and the lower pattern layer.

21. The display device of claim 1, further comprising:
a color filter layer comprising a plurality of filter portions that transmit light of different wavelengths, wherein:
the plurality of light control parts are disposed directly on the display panel; and
the color filter layer is disposed above the plurality of light control parts.

22. A display device comprising:
first, second, third, and fourth pixel regions that emit light of different wavelength ranges;
a display element layer that provides source light; and
a light control layer disposed on the display element layer, the light control layer comprising:
a plurality of light control parts, and
a division pattern layer dividing the plurality of light control parts, the division pattern layer comprising:
a lower pattern layer comprising:
a plurality of first barrier rib portions extending in a first direction and spaced apart from each other in a second direction perpendicular to the first direction, and
a plurality of second barrier rib portions extending in the second direction and spaced apart from each other in the first direction; and
an upper pattern layer disposed on the lower pattern layer, the upper pattern layer comprising a plurality of dam portions spaced apart from each other in the second direction,
wherein a distance between the plurality of dam portions neighboring each other in the second direction is greater than a distance between the plurality of first barrier rib portions neighboring each other in the second direction.

23. The display device of claim 22, wherein:
an opening defined by the plurality of first barrier rib portions and the plurality of second barrier rib portions is disposed in the lower pattern layer; and
a dam opening defined by the plurality of dam portions is disposed in the upper pattern layer.

24. The display device of claim 23, wherein:
the plurality of light control parts are disposed in the opening; and
a remaining light control part is disposed in the dam opening, the remaining light control part and the plurality of light control parts adjacent to the dam opening that emit light of a same wavelength range.

25. The display device of claim 23, wherein
the plurality of light control parts comprise:
a plurality of first light control parts disposed to be arranged in the first direction, the plurality of first light control parts that emit red light;
a plurality of second light control parts spaced apart from the first light control parts in the second direction, and disposed to be arranged in the first direction, the plurality of second light control parts that emit green light;
a plurality of third light control parts spaced apart from the second light control parts in the second direction, disposed to be arranged in the first direction, the plurality of third light control parts that emit blue light; and
a plurality of fourth light control parts spaced apart from the third light control parts in the second direction, disposed to be arranged in the first direction, the plurality of fourth light control parts that emit white light, and the first, second, third, and fourth light control parts are respectively disposed in the opening.

26. The display device of claim 25, wherein:
the plurality of first light control parts comprise a first quantum dot that converts the source light into red light;
the plurality of second light control parts comprise a second quantum dot that converts the source light into green light;
the plurality of third light control parts do not comprise a quantum dot; and
the plurality of fourth light control parts comprise the first quantum dot or both the first quantum dot and the second quantum dot.

27. The display device of claim 22, further comprising:
a color filter layer comprising first, second, third, and fourth filter portions respectively disposed to correspond to the first, second, third, and fourth pixel regions.

28. The display device of claim 22, further comprising:
a light blocking pattern layer that divides the first, second, third, and fourth pixel regions.

29. A method for manufacturing a display device, the method comprising:
providing a base member;
forming, on the base member, a division pattern layer comprising:
a plurality of first barrier rib portions extending in a first direction and spaced apart from each other by a first distance in a second direction perpendicular to the first direction,
a plurality of second barrier rib portions extending in the second direction, and
a plurality of dam portions disposed to have a second distance greater than the first distance in the second direction;
providing an initial printing resin comprising unreacted monomer in openings defined by the plurality of first barrier rib portions and the plurality of second barrier rib portions and dam openings defined by the plurality of dam portions;
providing an ink composition on the provided initial printing resin;
curing the ink composition; and
removing the initial printing resin to form a light control member comprising light control parts.

30. The method of claim 29, wherein the providing of the initial printing resin and the providing of the ink composition are performed by an inkjet printing method.

31. The method of claim 29, wherein:
the ink composition comprises a base monomer having a polymerization reacting group; and
the unreacted monomer is formed by removing the polymerization reacting group from the base monomer.

32. The method of claim 31, wherein the unreacted monomer has a vapor pressure of about 10⁻⁶ mmHg to about 10⁻¹ mmHg.

33. The method of claim 31, wherein the initial printing resin further comprises an organic solvent having a vapor pressure of about 1 mmHg or less.

34. The method of claim 29, wherein:
the base member comprises a base substrate and a color filter layer disposed on the base substrate; and
the division pattern layer is formed on a surface of the color filter layer.

35. The method of claim 34, further comprising:
providing a display panel comprising a display element layer; and
assembling the light control member and the display panel together.

36. The method of claim 29, wherein:
the base member is a display panel comprising a display element layer; and
the division pattern layer is formed directly on the display panel.
